(19) United States
(12) Patent Application Publication
(10) Pub. No.: US 2023/0010700 A1
(43) Pub. Date: Jan. 12, 2023

(54) METHOD AND SYSTEM FOR ENHANCING TARGET FEATURES OF A PATTERN IMAGED ONTO A SUBSTRATE

(71) Applicants: CYMER, LLC, San Diego, CA (US); ASML NETHERLANDS B.V., Veldhoven (NL)

(72) Inventors: Willard Earl CONLEY, San Diego, CA (US); Duan-Fu Stephen HSU, Fremont, CA (US)

(73) Assignees: CYMER, LLC, San Diego, CA (US); ASML NETHERLANDS B.V., Veldhoven (NL)

(21) Appl. No.: 17/780,287

(22) PCT Filed: Nov. 5, 2020
(86) PCT No.: PCT/EP2020/081020

§ 371 Date: May 26, 2022

Related U.S. Application Data
(60) Provisional application No. 62/942,362, filed on Dec. 2, 2019.
(60) Provisional application No. 63/031,802, filed on May 29, 2020.

(51) Int. Cl. G03F 7/20

(52) U.S. Cl. CPC G03F 7/70333; G03F 7/70441; G03F 7/70641

(57) ABSTRACT

Enhancing target features of a pattern imaged onto a substrate. This may include adding one or more assist features to a patterning device pattern in one or more locations adjacent to one or more target features in the patterning device pattern. The one or more assist features are added based on two or more different focus positions in the substrate. This can also include shifting the patterning device pattern and/or a design layout based on the two or more different focus positions and the one or more added assist features. This may be useful for improving across slit asymmetry. Adding the one or more assist features to the pattern and shifting the pattern and/or the design layout enhances the target features by reducing a shift caused by across slit asymmetry for a slit of a multifocal lithographic imaging apparatus. This may reduce the shift across an entire imaging field.

### CROSS-REFERENCE TO RELATED APPLICATIONS

This application claims priority of U.S. application 62/942,362 which was filed on Dec. 2, 2019 and U.S. application 63/031,802 which was filed on May 29, 2020 and are both incorporated herein in its entirety by reference.

### TECHNICAL FIELD

The description herein relates to a method and system for enhancing target features of a pattern imaged onto a substrate.

### BACKGROUND

A lithographic projection apparatus can be used, for example, in the manufacture of integrated circuits (ICs). A patterning device (e.g., a mask) may contain or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate includes a plurality of adjacent target portions to which the pattern is transferred successively by the lithographic projection apparatus, one target portion at a time. In one type of lithographic projection apparatus, the pattern on the entire patterning device is transferred onto one target portion in one operation. Such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern on the patterning device are transferred to one target portion progressively. Since, in general, the lithographic projection apparatus will have a reduction ratio M (e.g., 4), and the reduction ratio can be different in x and y direction features the speed F at which the substrate is moved will be 1/M times that at which the projection beam scans the patterning device. More information with regard to lithographic devices as described herein can be gleaned, for example, from U.S. Pat. No. 6,046,792, incorporated herein by reference.

Prior to transferring the pattern from the patterning device to the substrate, the substrate may undergo various procedures, such as priming, resist coating and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish the individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

Thus, manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc.

As noted, lithography is a central step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

As semiconductor manufacturing processes continue to advance, the dimensions of functional elements have continually been reduced while the number of functional elements, such as transistors, per device has been steadily increasing over decades, following a trend commonly referred to as “Moore's law”. At the current state of technology, layers of devices are manufactured using lithographic projection apparatuses that project a design layout onto a substrate using illumination from a deep-ultraviolet illumination source, creating individual functional elements having dimensions well below 100 nm, i.e. less than half the wavelength of the radiation from the illumination source (e.g., a 193 nm illumination source).

This process in which features with dimensions smaller than the classical resolution limit of a lithographic projection apparatus are printed, is commonly known as low-k₁ lithography, according to the resolution formula CD=k₁×λ/NA, where λ is the wavelength of radiation employed (currently in most cases 248 nm or 193 nm), NA is the numerical aperture of projection optics in the lithographic projection apparatus, CD is the “critical dimension”—generally the smallest feature size printed—and k₁ is an empirical resolution factor. In general, the smaller k₁ the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the patterning device. These include, for example, but not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET).

### SUMMARY

According to an embodiment, there is provided a non-transitory computer readable medium having instructions thereon. The instructions, when executed by a computer, cause the computer to place one or more assist features in a design layout in one or more locations adjacent to one or more target features in the design layout. The design layout is configured to be used to pattern a substrate. The one or more assist features are placed based on two or more different focus positions on the substrate. The instructions also cause the computer to shift the design layout (e.g., a circuit design) based on the two or more different focus positions and the one or more placed assist features. The shifting is configured to enhance the one or more target features when the one or more target features are patterned on the substrate.

In an embodiment, shifting the design layout comprises repositioning a patterning device pattern, determined based on the design layout, relative to the substrate.

In an embodiment, the enhancing is achieved by reducing a shift that would otherwise be caused by across slit asymmetry for a slit through which imaging radiation passes during imaging of the substrate.

In an embodiment, the across slit asymmetry is associated with a Z2 Zernike polynomial or with collateral Zernike polynomials.

In an embodiment, placing the one or more assist features and shifting the design layout comprises simulating adjustment a numerical aperture (NA), a sigma, a best focus, and/or a wavelength peak separation associated with imaging radiation to optimize the one or more assist features. In an embodiment, the optimization comprises through slit optimization.

In an embodiment, placing the one or more assist features and shifting the design layout comprises electromagnetic or scalar modeling of the one or more assist features and the shifting of the design layout with an electronic model.

In an embodiment, the instructions are further configured to cause the computer to determine through slit assist feature rules and place the one or more assist features based on the optimized assist features, and apply a full field optical proximity correction for the design layout. The full field optical proximity correction may be model based or rules based. Applying the full field optical proximity correction comprises: applying, based on the shifted design layout, a through slit repositioning shift to the one or more target features of the design layout; applying the optimized through slit assist features; and applying a main feature bias.

In an embodiment, the through slit assist feature position and width are determined via a model based optimization with a custom cost function and optimum assist feature positions and widths are converted into a rule table. The custom cost function comprises terms for target feature side wall angle, side wall angle linearity, side wall angle symmetry, and pattern placement error.

In an embodiment, the one or more target features (when formed in the substrate) have sidewalls, and wherein placing the one or more assist features and shifting the design layout are performed to achieve a required sidewall angle, side wall angle linearity, and/or side wall angle symmetry.

In an embodiment, optimized imaging radiation having two or more different wavelengths controls the two or more different focus positions on the substrate for a single exposure of the substrate to the imaging radiation.

In an embodiment, the one or more assist features and the shifted design layout are configured to enhance the one or more target features in the substrate by improving one or both of a symmetry of the one or more target features, or placement of the one or more target features, in the substrate.

In an embodiment, placing the one or more assist features comprises determining a quantity, a shape, a size, a position, and/or an orientation of the one or more assist features relative to the one or more target features based on two or more different wavelengths of imaging radiation associated with the different focus positions. In an embodiment, the shape, size, position, and/or orientation of the one or more assist features are configured such that the one or more assist features are not formed in the substrate.

In an embodiment, placing the one or more assist features and shifting the design layout are performed for a semiconductor manufacturing process.

According to another embodiment, there is provided a method for enhancing one or more target features when the one or more target features are patterned on a substrate. The method comprises placing one or more assist features in a design layout in one or more locations adjacent to one or more target features in the design layout. The design layout is configured to be used to pattern the substrate. The one or more assist features are placed based on two or more different focus positions on the substrate. The method also comprises shifting the design layout (e.g., a circuit design) based on the two or more different focus positions and the one or more placed assist features. The shifting is configured to enhance the one or more target features when the one or more target features are patterned on the substrate.

In an embodiment, shifting the design layout comprises repositioning a patterning device pattern, determined based on the design layout, relative to the substrate.

In an embodiment, the enhancing is achieved by reducing a shift that would otherwise be caused by across slit asymmetry for a slit through which imaging radiation passes during imaging of the substrate.

In an embodiment, the across slit asymmetry is associated with a Z2 Zernike polynomial or with collateral Zernike polynomials.

In an embodiment, placing the one or more assist features and shifting the design layout comprises simulating adjustment of a numerical aperture (NA), a sigma, a best focus, and/or a wavelength peak separation associated with imaging radiation to optimize the one or more assist features. In an embodiment, the optimization comprises through slit optimization.

In an embodiment, placing the one or more assist features and shifting the design layout comprises electromagnetic or scalar modeling of the one or more assist features and the shifting of the design layout with an electronic model.

In an embodiment, the method further comprises determining through slit assist feature rules and placing the one or more assist features based on the optimized assist features, and applying a full field optical proximity correction for the design layout. The full field optical proximity correction may be model based or rules based. Applying the full field optical proximity correction comprises: applying, based on the shifted design layout, a through slit repositioning shift to the one or more target features of the design layout; applying the optimized through slit assist features; and applying a main feature bias.

In an embodiment, the through slit assist feature rules are determined based on a custom cost function. The custom cost function comprises terms for target feature side wall angle, side wall angle linearity, side wall angle symmetry, and pattern placement error.

In an embodiment, the one or more target features have sidewalls. Placing the one or more assist features and shifting the design layout are performed to achieve a required sidewall angle, side wall angle linearity, and/or side wall angle symmetry.

In an embodiment, optimized imaging radiation having two or more different wavelengths controls the two or more different focus positions on the substrate for a single exposure of the substrate to the imaging radiation.

In an embodiment, the one or more assist features and the shifted design layout are configured to enhance the one or more target features in the substrate by improving one or both of a symmetry of the one or more target features, or placement of the one or more target features, in the substrate.

In an embodiment, placing the one or more assist features comprises determining a quantity, a shape, a size, a position, and/or an orientation of the one or more assist features relative to the one or more target features based on two or more different wavelengths of imaging radiation associated with the different focus positions. In an embodiment, the shape, size, position, and/or orientation of the one or more assist features are configured such that the one or more assist features are not formed in the substrate.

In an embodiment, placing the one or more assist features and shifting the design layout are performed for a semiconductor manufacturing process.

According to another embodiment, there is provided a method for enhancing target features of a pattern imaged onto a substrate. The method comprises determining two or more different focus positions on the substrate for imaging radiation; and adding, based on the two or more different focus positions, one or more assist features to the pattern in one or more locations proximate to one or more of the target features of the pattern. The added one or more assist features are configured to enhance the target features on the substrate.

In an embodiment, the two or more different focus positions on the substrate are for imaging radiation having two or more different wavelengths, and are determined for a single exposure of the layer to the imaging radiation.

In an embodiment, the imaging radiation comprises two or more different colors that correspond to the two or more different wavelengths.

In an embodiment, the two or more different focus positions are determined based on the two or more different wavelengths of imaging radiation.

In an embodiment, the one or more assist features comprise one or more sub-resolution assist features.

In an embodiment, the added one or more assist features are configured to enhance the target features on the substrate by improving one or both of a symmetry of the target features of the pattern, or placement of the target features of the pattern, in the substrate.

In an embodiment, the method further comprises determining an image associated with the substrate by adding the one or more assist features to the pattern in the one or more locations proximate to one or more of the target features; and determining the image based on the one or more added assist features and the target features.

In an embodiment, the image is an aerial image.

In an embodiment, determining the image based on the one or more added assist features and the one or more target features improves one or both of a symmetry of the target features of the pattern, or placement of the target features of the pattern, in the image.

In an embodiment, one or both of the symmetry of the target features of the pattern, or the placement of the target features of the pattern in the image are improved relative to a symmetry and/or placement of target features in a different image determined without considering the assist features.

In an embodiment, adding the one or more assist features to the pattern in the one or more locations proximate to the one or more target features of the pattern comprises determining a shape, a size, a position, and/or an orientation of the one or more assist features relative to the one or more target features.

In an embodiment, adding the one or more assist features to the pattern enhances the target features by reducing a shift caused by across slit asymmetry for a slit of a multifocal lithographic imaging apparatus.

In an embodiment, the across slit asymmetry is associated with a Z2 Zernike polynomial.

In an embodiment, the across slit asymmetry is associated with collateral Zernike polynomials.

In an embodiment, different ones of the one or more assist features correspond to one or more different slit positions in the slit.

In an embodiment, a shape, size, position, and/or orientation of the one or more assist features are configured such that the one or more assist features are not formed on the substrate.

In an embodiment, adding one or more assist features to the pattern in the one or more locations proximate to the one or more target features of the pattern comprises electronically modeling the one or more assist features in the pattern.

In an embodiment, the pattern comprises a mask pattern.

In an embodiment, determining the two or more different focus positions on the substrate for the imaging radiation; and adding the one or more assist features to the pattern in the one or more locations proximate to the one or more target features of the pattern are performed for a semiconductor manufacturing process.

In an embodiment, adding one or more assist features to the pattern in one or more locations proximate to one or more target features of the pattern comprises adding one assist feature on one side of a given target feature.

In an embodiment, adding one or more assist features to the pattern in one or more locations proximate to one or more target features of the pattern comprises adding two or more assist features on one side of a given target feature.

In an embodiment, adding one or more assist features to the pattern in one or more locations proximate to one or more target features of the pattern comprises adding at least one assist feature on each of two different sides of a given target feature.

According to another embodiment, a non-transitory computer readable medium is provided. The medium has instructions stored thereon. The instructions, when executed by a computer, implementing the method of any of the embodiments described herein.

According to another embodiment, a non-transitory computer readable medium is provided. The medium has instructions thereon. The instructions, when executed by a computer, causing the computer to: determine two or more different focus positions on the substrate for imaging radiation; and add, based on the two or more different focus positions, one or more assist features to the pattern in one or more locations proximate to one or more of the target features of the pattern. The added one or more assist features are configured to enhance the target features on the substrate.

In an embodiment, the two or more different focus positions on the substrate are for imaging radiation having two or more different wavelengths, and are determined for a single exposure of the layer to the imaging radiation.

In an embodiment, the one or more assist features comprise one or more sub-resolution assist features.

In an embodiment, the added one or more assist features are configured to enhance the target features on the substrate by improving one or both of a symmetry of the target features of the pattern, or placement of the target features of the pattern, in the substrate.

In an embodiment, the instructions are further configured to cause the computer to determine an aerial image associated with the substrate by adding the one or more assist features to the pattern in the one or more locations proximate to one or more of the target features; and determine the aerial image based on the one or more added assist features and the target features.

In an embodiment, one or both of the symmetry of the target features of the pattern, or the placement of the target features of the pattern in the aerial image are improved relative to a symmetry and/or placement of target features in a different image determined without considering the assist features.

In an embodiment, adding the one or more assist features to the pattern in the one or more locations proximate to the one or more target features of the pattern comprises determining a shape, a size, a position, and/or an orientation of the one or more assist features relative to the one or more target features.

In an embodiment, adding the one or more assist features to the pattern enhances the target features by reducing a shift caused by across slit asymmetry for a slit of a multifocal lithographic imaging apparatus.

In an embodiment, different ones of the one or more assist features correspond to one or more different slit positions in the slit.

In an embodiment, a shape, size, position, and/or orientation of the one or more assist features are configured such that the one or more assist features are not formed on the substrate.

In an embodiment, adding one or more assist features to the pattern in the one or more locations proximate to the one or more target features of the pattern comprises electronically modeling the one or more assist features in the pattern.

According to another embodiment, a lithography apparatus is described. The apparatus comprises: an illumination source and projection optics configured to image a pattern onto a substrate; and one or more processors configured by machine readable instructions to: determine two or more different focus positions on the substrate for imaging radiation; and add, based on the two or more different focus positions, one or more assist features to the pattern in one or more locations proximate to one or more of the target features of the pattern, the added one or more assist features configured to enhance the target features on the substrate.

In an embodiment, the two or more different focus positions on the substrate are for imaging radiation having two or more different wavelengths, and are determined for a single exposure of the layer to the imaging radiation.

In an embodiment, the one or more assist features comprise one or more sub-resolution assist features.

In an embodiment, the added one or more assist features are configured to enhance the target features on the substrate by improving one or both of a symmetry of the target features of the pattern, or placement of the target features of the pattern, in the substrate.

In an embodiment, the one or more processors are further configured to determine an image associated with the substrate by adding the one or more assist features to the pattern in the one or more locations proximate to one or more of the target features; and determine the image based on the one or more added assist features and the target features.

In an embodiment, the image is an aerial image.

In an embodiment, the one or more processors are configured such that adding the one or more assist features to the pattern in the one or more locations proximate to the one or more target features of the pattern comprises determining a shape, a size, a position, and/or an orientation of the one or more assist features relative to the one or more target features.

In an embodiment, the one or more processors are configured such that adding the one or more assist features to the pattern enhances the target features by reducing a shift caused by across slit asymmetry for a slit of a multifocal lithographic imaging apparatus.

In an embodiment, different ones of the one or more assist features correspond to one or more different slit positions in the slit.

In an embodiment, the one or more processors are configured such that adding one or more assist features to the pattern in one or more locations proximate to one or more target features of the pattern comprises adding one assist feature on one side of a given target feature.

In an embodiment, the one or more processors are configured such that adding one or more assist features to the pattern in one or more locations proximate to one or more target features of the pattern comprises adding two or more assist features on one side of a given target feature.

According to another embodiment, a method for enhancing target features of a pattern imaged onto a substrate is described. The method comprises using imaging radiation to create two or more different focus positions on the substrate; and adding, based on the two or more different focus positions, one or more assist features to the pattern in one or more locations proximate to one or more of the target features of the pattern. The added one or more assist features are configured to enhance the target features on the substrate. The method comprises causing the target features of the pattern to be imaged onto the substrate based on the one or more added assist features and the target features.

According to another embodiment, there is provided a computer implemented method to enhance a process of imaging a portion of a design layout onto substrate. The method comprises: determining two or more different focus positions on the substrate for imaging radiation; and placing, based on the two or more different focus positions, one or more assist features asymmetrically into the design layout for imaging in one or more locations proximate to a target feature in the design layout for imaging.

### BRIEF DESCRIPTION OF THE DRAWINGS

The accompanying drawings, which are incorporated in and constitute a part of this specification, show certain aspects of the subject matter disclosed herein and, together with the description, help explain some of the principles associated with the disclosed implementations. In the drawings,

FIG. 1 illustrates a block diagram of various subsystems of a lithographic projection apparatus, according to an embodiment.

FIG. 2 illustrates an exemplary flow chart for simulating lithography in a lithographic projection apparatus, according to an embodiment.

FIG. 3 illustrates an example method for enhancing target features of a pattern imaged onto a substrate, according to an embodiment.

FIG. 4 illustrates single focal imaging (e.g., imaging with radiation of a single wavelength or color) for a thick layer of photoresist, according to an embodiment.

FIG. 5 illustrates using an additional etch process to improve sidewall angle uniformity and linearity for a feature of a pattern formed on a substrate using single focal imaging, according to an embodiment.

FIG. 6 illustrates multifocal imaging, according to an embodiment.

FIG. 7A illustrates an example of image shift across different slit positions for a slit in a multifocal lithographic imaging apparatus, according to an embodiment.

FIG. 7B illustrates a shift associated with different (e.g., aerial) images and that correspond to two different wavelengths of radiation used for multifocal imaging, according to an embodiment.

FIG. 8 illustrates an intensity versus mask position plot for a portion of an aerial image associated with a pattern feature generated using (or based on) single focal imaging, according to an embodiment.

FIG. 9 illustrates a different intensity versus mask position plot for the portion of the aerial image associated with pattern feature generated using (or based on) multifocal imaging, according to an embodiment.

FIG. 10 illustrates an assist feature added to a pattern, according to an embodiment.

FIG. 11 illustrates a series of intensity versus mask position plots for a portion of an aerial image associated with a target feature and an assist feature, according to an embodiment.

FIG. 12 illustrates an intensity versus mask position plot for a portion of an aerial image associated with a target feature and two assist features, according to an embodiment.

FIG. 13 illustrates the effect of adding an assist feature proximate to a target feature in a pattern on a resist profile, according to an embodiment.

FIG. 14 illustrates various example resist profiles 1400 generated (e.g., modeled) based on different added assist features, according to an embodiment.

FIG. 15 illustrates shifting a patterning device pattern and/or a design layout based on two or more different focus positions and one or more added assist features, according to an embodiment.

FIG. 16 illustrates a first example of images of a model of sidewalls of a shifted target pattern feature, according to an embodiment.

FIG. 17 illustrates a second example of images of a model of sidewalls of a shifted target pattern feature, according to an embodiment.

FIG. 18 illustrates a flow comprising determining through slit assist feature and pattern shift rules and placing the one or more assist features based on the optimized added assist features, and applying a full field optical proximity correction for a patterning device pattern across a slit, according to an embodiment.

FIG. 19 provides further detail about the operations shown in FIG. 18, according to an embodiment.

FIG. 20 illustrates an example of an optimized through slit pattern and assist feature rules, according to an embodiment.

FIG. 21 illustrates an example of optimizing a best focus position in a resist layer for a multifocal imaging process, according to an embodiment.

FIG. 22 illustrates adjusting (e.g., tuning) and/or otherwise optimizing a wavelength peak separation of multifocal imaging radiation, according to an embodiment.

FIG. 23 illustrates an example of a custom cost function, according to an embodiment.

FIG. 24 is a block diagram of an example computer system, according to an embodiment.

FIG. 25 is a schematic diagram of a lithographic projection apparatus, according to an embodiment.

FIG. 26 is a schematic diagram of another lithographic projection apparatus, according to an embodiment.

FIG. 27 is a detailed view of the lithographic projection apparatus, according to an embodiment.

FIG. 28 is a detailed view of the source collector module of the lithographic projection apparatus, according to an embodiment.

### DETAILED DESCRIPTION

The present disclosure describes use of assist features and design layout (e.g., circuit design) shifting to improve across slit asymmetry in patterned features. The asymmetry may be from image shift that occurs during a multifocal imaging process (e.g., imaging using radiation having multiple wavelengths and/or colors). Multifocal imaging comprises the formation of an (e.g., averaged) aerial image (described herein) based on imaging radiation having two or more different wavelengths (and/or colors). Using imaging radiation having two or more different wavelengths (and/or colors) creates two or more different focus positions in a substrate. The two or more different focus positions in the substrate are associated with a single exposure of the layer to the imaging radiation, for example. A multifocal imaging process may be used to increase depth of focus, image sidewall angle, and/or enhance other aspects of integrated circuit manufacturing. However, in multifocal imaging, image shift occurs across a slit, and the impact or amount of the shift is dependent on the differences between the two or more wavelengths.

The present method(s) and apparatus(es) are configured to reduce or eliminate asymmetric effects across a slit due to chromatic aberrations in multifocal (e.g., multi-wavelength and/or multi-color) imaging. The present method(s) and apparatus(s) are configured to enhance the process of patterning a design layout onto a substrate. The present method(s) and apparatus(es) are configured to add and/or otherwise place, based on the two or more different focus positions, one or more assist features to a design layout in one or more locations proximate to one or more of the target features of the design layout. The one or more assist features may be added asymmetrically, symmetrically, and/or in other orientations. The present method(s) and apparatus(es) are also configured to shift a patterning device pattern and/or the design layout (e.g., the circuit design) relative to the substrate based on the two or more different focus positions and the one or more added assist features. The one or more added assist features and the shifted patterning device pattern and/or design layout are configured to enhance the one or more target features in the substrate. In some embodiments, adding the one or more assist features and the shifting may be performed as part of a computational optimization of a multifocal imaging process flow, as described herein.

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid crystal display panels, thin film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

A patterning device can comprise, or can form, one or more design layouts. The design layout can be generated utilizing CAD (computer-aided design) programs. This process is often referred to as EDA (electronic design automation). Most CAD programs follow a set of predetermined design rules in order to create functional design layouts/patterning devices. These rules are set based processing and design limitations. For example, design rules define the space tolerance between devices (such as gates, capacitors, etc.) or interconnect lines, to ensure that the devices or lines do not interact with one another in an undesirable way. One or more of the design rule limitations may be referred to as a “critical dimension” (CD). A critical dimension of a device can be defined as the smallest width of a line or hole, or the smallest space between two lines or two holes. Thus, the CD regulates the overall size and density of the designed device. One of the goals in device fabrication is to faithfully reproduce the original design intent on the substrate (via the patterning device).

The term “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective; binary, phase-shifting, hybrid, etc.), examples of other such patterning devices include a programmable mirror array. An example of such a device is a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic means. Examples of other such patterning devices also include a programmable LCD array. An example of such a construction is given in U.S. Pat. No. 5,229,872, which is incorporated herein by reference.

The term “projection optics” as used herein should be broadly interpreted as encompassing various types of optical systems, including refractive optics, reflective optics, apertures and catadioptric optics, for example. The term “projection optics” may also include components operating according to any of these design types for directing, shaping or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

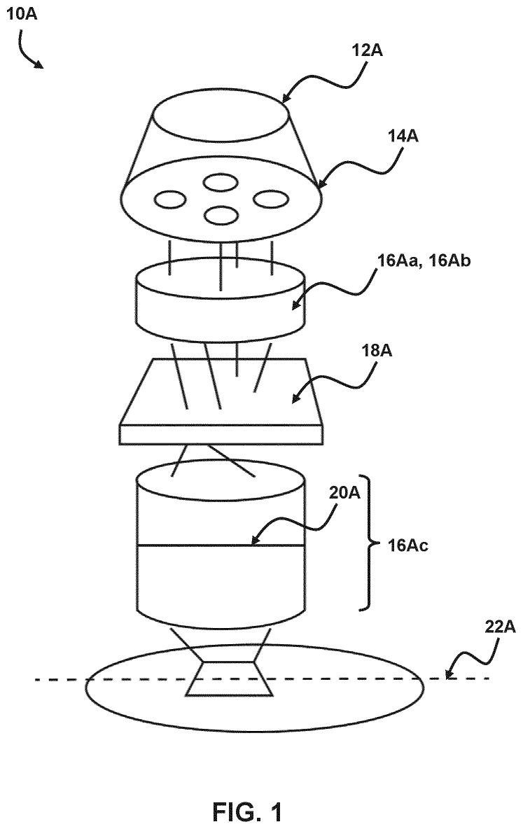

FIG. 1 illustrates a block diagram of various subsystems of a lithographic projection apparatus 10A, according to an embodiment. Major components are a radiation source 12A, which may be a deep-ultraviolet excimer laser source or other type of source including an extreme ultra violet (EUV) source (the lithographic projection apparatus itself need not have the radiation source), illumination optics which, e.g., define the partial coherence (denoted as sigma) and which may include optics components 14A, 16Aa and 16Ab that shape radiation from the source 12A; a patterning device (or mask) 18A; and transmission optics 16Ac that project an image of the patterning device pattern onto a substrate plane 22A. It should be noted that FIG. 1 is intended as a general representation of a lithographic projection apparatus. The apparatus can be of a reflective type, or it may also be of a transmissive type, for example.

A pupil 20A can be included with transmission optics 16Ac. In some embodiments, there can be one or more pupils before and/or after mask 18A. As described in further detail herein, pupil 20A can provide patterning of the light that ultimately reaches substrate plane 22A. An adjustable filter or aperture at the pupil plane of the projection optics may restrict the range of beam angles that impinge on the substrate plane 22A, where the largest possible angle defines the numerical aperture of the projection optics NA=n sin(Θₘₐₓ), wherein n is the refractive index of the media between the substrate and the last element of the projection optics, and Θₘₐₓ is the largest angle of the beam exiting from the projection optics that can still impinge on the substrate plane 22A.

In a lithographic projection apparatus, a source provides illumination (i.e. radiation) to a patterning device and projection optics direct and shape the illumination, via the patterning device, onto a substrate. The projection optics may include at least some of the components 14A, 16Aa, 16Ab and 16Ac. An aerial image (AI) is the radiation intensity distribution at substrate level. A resist model can be used to calculate the resist image from the aerial image, an example of which can be found in U.S. Patent Application Publication No. US 2009-0157630, the disclosure of which is hereby incorporated by reference in its entirety. The resist model is related to properties of the resist layer (e.g., effects of chemical processes which occur during exposure, post-exposure bake (PEB) and development). Optical properties of the lithographic projection apparatus (e.g., properties of the illumination, the patterning device and the projection optics) dictate the aerial image and can be defined in an optical model. Since the patterning device used in the lithographic projection apparatus can be changed, it is desirable to separate the optical properties of the patterning device from the optical properties of the rest of the lithographic projection apparatus including at least the source and the projection optics. Details of techniques and models used to transform a design layout into various lithographic images (e.g., an aerial image, a resist image, etc.), apply OPC using those techniques and models and evaluate performance (e.g., in terms of process window) are described in U.S. Patent Application Publication Nos. US 2008-0301620, 2007-0050749, 2007-0031745, 2008-0309897, 2010-0162197, and 2010-0180251, the disclosure of each which is hereby incorporated by reference in its entirety.

One aspect of understanding a lithographic process is understanding the interaction of the radiation and the patterning device. The electromagnetic field of the radiation after the radiation passes the patterning device may be determined from the electromagnetic field of the radiation before the radiation reaches the patterning device and a function that characterizes the interaction. This function may be referred to as the mask transmission function (which can be used to describe the interaction by a transmissive patterning device and/or a reflective patterning device).

The mask transmission function may have a variety of different forms. One form is binary. A binary mask transmission function has either of two values (e.g., zero and a positive constant) at any given location on the patterning device. A mask transmission function in the binary form may be referred to as a binary mask. Another form is continuous. Namely, the modulus of the transmittance (or reflectance) of the patterning device is a continuous function of the location on the patterning device. The phase of the transmittance (or reflectance) may also be a continuous function of the location on the patterning device. A mask transmission function in the continuous form may be referred to as a continuous tone mask or a continuous transmission mask (CTM). For example, the CTM may be represented as a pixelated image, where each pixel may be assigned a value between 0 and 1 (e.g., 0.1, 0.2, 0.3, etc.) instead of binary value of either 0 or 1. In an embodiment, CTM may be a pixelated gray scale image, where each pixel having values (e.g., within a range [−255, 255], normalized values within a range [0, 1] or [−1, 1] or other appropriate ranges).

The thin-mask approximation, also called the Kirchhoff boundary condition, is widely used to simplify the determination of the interaction of the radiation and the patterning device. The thin-mask approximation assumes that the thickness of the structures on the patterning device is very small compared with the wavelength and that the widths of the structures on the mask are very large compared with the wavelength. Therefore, the thin-mask approximation assumes the electromagnetic field after the patterning device is the multiplication of the incident electromagnetic field with the mask transmission function. However, as lithographic processes use radiation of shorter and shorter wavelengths, and the structures on the patterning device become smaller and smaller, the assumption of the thin-mask approximation can break down. For example, interaction of the radiation with the structures (e.g., edges between the top surface and a sidewall) because of their finite thicknesses (“mask 3D effect” or “M3D”) may become significant. Encompassing this scattering in the mask transmission function may enable the mask transmission function to better capture the interaction of the radiation with the patterning device. A mask transmission function under the thin-mask approximation may be referred to as a thin-mask transmission function. A mask transmission function encompassing M3D may be referred to as a M3D mask transmission function.

According to an embodiment of the present disclosure, one or more images may be generated. The images include various types of signal that may be characterized by pixel values or intensity values of each pixel. Depending on the relative values of the pixel within the image, the signal may be referred as, for example, a weak signal or a strong signal, as may be understood by a person of ordinary skill in the art. The term “strong” and “weak” are relative terms based on intensity values of pixels within an image and specific values of intensity may not limit scope of the present disclosure. In an embodiment, the strong and weak signal may be identified based on a selected threshold value. In an embodiment, the threshold value may be fixed (e.g., a midpoint of a highest intensity and a lowest intensity of pixel within the image. In an embodiment, a strong signal may refer to a signal with values greater than or equal to an average signal value across the image and a weak signal may refer to signal with values less than the average signal value. In an embodiment, the relative intensity value may be based on percentage. For example, the weak signal may be signal having intensity less than 50% of the highest intensity of the pixel (e.g., pixels corresponding to target pattern may be considered pixels with highest intensity) within the image. Furthermore, each pixel within an image may considered as a variable. According to the present embodiment, derivatives or partial derivative may be determined with respect to each pixel within the image and the values of each pixel may be determined or modified according to a cost function based evaluation and/or gradient based computation of the cost function. For example, a CTM image may include pixels, where each pixel is a variable that can take any real value.

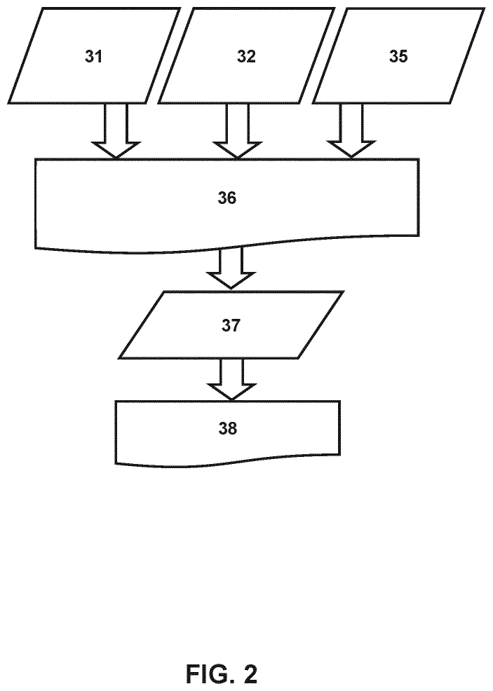

FIG. 2 illustrates an exemplary flow chart for simulating lithography in a lithographic projection apparatus, according to an embodiment. Source model 31 represents optical characteristics (including radiation intensity distribution and/or phase distribution) of the source. Projection optics model 32 represents optical characteristics (including changes to the radiation intensity distribution and/or the phase distribution caused by the projection optics) of the projection optics. Design layout model 35 represents optical characteristics of a design layout (including changes to the radiation intensity distribution and/or the phase distribution caused by design layout 33), which is the representation of an arrangement of features on or formed by a patterning device. Aerial image 36 can be simulated from design layout model 35, projection optics model 32, and design layout model 35. Resist image 38 can be simulated from aerial image 36 using resist model 37. Simulation of lithography can, for example, predict contours and CDs in the resist image.

More specifically, source model 31 can represent the optical characteristics of the source that include, but are not limited to, numerical aperture settings, illumination sigma (σ) settings as well as any particular illumination shape (e.g. off-axis radiation sources such as annular, quadrupole, dipole, etc.). Projection optics model 32 can represent the optical characteristics of the projection optics, including aberration, distortion, one or more refractive indexes, one or more physical sizes, one or more physical dimensions, etc. Design layout model 35 can represent one or more physical properties of a physical patterning device, as described, for example, in U.S. Pat. No. 7,587,704, which is incorporated by reference in its entirety. The objective of the simulation is to accurately predict, for example, edge placement, aerial image intensity slope and/or CD, which can then be compared against an intended design. The intended design is generally defined as a pre-OPC design layout which can be provided in a standardized digital file format such as GDSII or OASIS or another file format.

From this design layout, one or more portions may be identified, which are referred to as “clips”. In an embodiment, a set of clips is extracted, which represents the complicated patterns in the design layout (typically about 50 to 1000 clips, although any number of clips may be used). These patterns or clips represent small portions (i.e. circuits, cells or patterns) of the design and more specifically, the clips typically represent small portions for which particular attention and/or verification is needed. In other words, clips may be the portions of the design layout, or may be similar or have a similar behavior of portions of the design layout, where one or more critical features are identified either by experience (including clips provided by a customer), by trial and error, or by running a full-chip simulation. Clips may contain one or more test patterns or gauge patterns.

An initial larger set of clips may be provided a priori by a customer based on one or more known critical feature areas in a design layout which require particular image optimization. Alternatively, in another embodiment, an initial larger set of clips may be extracted from the entire design layout by using some kind of automated (such as machine vision) or manual algorithm that identifies the one or more critical feature areas.

In a lithographic projection apparatus, as an example, a cost function may be expressed as

CF(z₁,z₂, . . . ,z_{N})=Σₚ₌₁^{p}wₚfₚ²(z₁,z₂, . . . ,z_{N}) (Eq. 1)

where (z₁, z₂, . . . , z_{N}) are N design variables or values thereof, fₚ (z₁, z₂, . . . , z_{N}) can be a function of the design variables (z₁, z₂, . . . , z_{N}) such as a difference between an actual value and an intended value of a characteristic for a set of values of the design variables of (z₁, z₂, . . . , z_{N}). wₚ is a weight constant associated with fₚ (z₁, z₂, . . . , z_{N}). For example, the characteristic may be a position of an edge of a pattern, measured at a given point on the edge. Different fₚ (z₁, z₂, . . . , z_{N}) may have different weight wₚ. For example, if a particular edge has a narrow range of permitted positions, the weight wₚ for the fₚ (z₁, z₂, . . . , z_{N}) representing the difference between the actual position and the intended position of the edge may be given a higher value. fₚ (z₁, z₂, . . . , z_{N}) can also be a function of an interlayer characteristic, which is in turn a function of the design variables (z₁, z₂, . . . , z_{N}). Of course, CF (z₁, z₂, . . . , z_{N}) is not limited to the form in Eq. 1. CF (z₁, z₂, . . . , z_{N}) can be in any other suitable form.

The cost function may represent any one or more suitable characteristics of the lithographic projection apparatus, lithographic process or the substrate, for instance, focus, CD, image shift, image distortion, image rotation, stochastic variation, throughput, local CD variation, process window, an interlayer characteristic, or a combination thereof. In one embodiment, the design variables (z₁, z₂, . . . , z_{N}) comprise one or more selected from dose, global bias of the patterning device, and/or shape of illumination. Since it is the resist image that often dictates the pattern on a substrate, the cost function may include a function that represents one or more characteristics of the resist image. For example, fₚ (z₁, z₂, . . . , z_{N}) can be simply a distance between a point in the resist image to an intended position of that point (i.e., edge placement error EPEₚ(z₁, z₂, . . . , z_{N}). The design variables can include any adjustable parameter such as an adjustable parameter of the source, the patterning device, the projection optics, dose, focus, etc.

The lithographic apparatus may include components collectively called a “wavefront manipulator” that can be used to adjust the shape of a wavefront and intensity distribution and/or phase shift of a radiation beam. In an embodiment, the lithographic apparatus can adjust a wavefront and intensity distribution at any location along an optical path of the lithographic projection apparatus, such as before the patterning device, near a pupil plane, near an image plane, and/or near a focal plane. The wavefront manipulator can be used to correct or compensate for certain distortions of the wavefront and intensity distribution and/or phase shift caused by, for example, the source, the patterning device, temperature variation in the lithographic projection apparatus, thermal expansion of components of the lithographic projection apparatus, etc. Adjusting the wavefront and intensity distribution and/or phase shift can change values of the characteristics represented by the cost function. Such changes can be simulated from a model or actually measured. The design variables can include parameters of the wavefront manipulator.

The design variables may have constraints, which can be expressed as (z₁, z₂, . . . , z_{N})∈Z, where Z is a set of possible values of the design variables. One possible constraint on the design variables may be imposed by a desired throughput of the lithographic projection apparatus. Without such a constraint imposed by the desired throughput, the optimization may yield a set of values of the design variables that are unrealistic. For example, if the dose is a design variable, without such a constraint, the optimization may yield a dose value that makes the throughput economically impossible. However, the usefulness of constraints should not be interpreted as a necessity. For example, the throughput may be affected by the pupil fill ratio. For some illumination designs, a low pupil fill ratio may discard radiation, leading to lower throughput. Throughput may also be affected by the resist chemistry. Slower resist (e.g., a resist that requires higher amount of radiation to be properly exposed) leads to lower throughput.

As used herein, the term “process model” means a model that includes one or more models that simulate a patterning process. For example, a process model can include any combination of: an optical model (e.g., that models a lens system/projection system used to deliver light in a lithography process and may include modelling the final optical image of light that goes onto a photoresist), a resist model (e.g., that models physical effects of the resist, such as chemical effects due to the light), an optical proximity correction (OPC) model (e.g., that can be used to make masks or reticles and may include sub-resolution resist features (SRAFs), etc.).

As used herein, the term “concurrently” means that two or more things are occurring at approximately, but not necessarily exactly, at the same time. For example, varying a pupil design concurrently with a mask pattern can mean making a small modification to a pupil design, then making a small adjustment to a mask pattern, and then another modification to the pupil design, and so on. However, the present disclosure contemplates that in some parallel processing applications, concurrency can refer to operations occurring at the same time, or having some overlapping in time.

The present disclosure provides apparatuses, methods and computer program products which, among other things, relate to modifying or optimizing features of a lithography apparatus in order to increase performance and manufacturing efficiency. The features that can be modified can include an optical spectrum of light used in the lithography process, a mask, a pupil, etc. Any combination of these features (and possibly others) can be implemented in order to improve, for example, a depth of focus, a process window, a contrast, or the like, of a lithography apparatus. In some embodiments, modification of one feature affects the other features. In this way, to achieve the desired improvements, multiple features can be concurrently modified/varied, as described below.

As described above, the present disclosure describes the use of assist features and pattern and/or design layout (e.g., circuit design) shifting to improve across slit asymmetry in patterned features from image shift that occurs during a multifocal imaging process (e.g., imaging using radiation having multiple wavelengths and/or colors). A multifocal imaging process may be used to increase depth of focus, image sidewall angle, and/or enhance other aspects of integrated circuit manufacturing. However, in multifocal imaging, image shift occurs across a slit, and the impact or amount of the shift is dependent on the differences between the multiple wavelengths.

The present method(s) and apparatus(es) are configured to enhance the process of patterning (e.g., imaging) a design layout onto a substrate. The present method(s) and apparatus(es) are configured to reduce or eliminate asymmetric effects across a slit due to chromatic aberrations in multifocal (e.g., multi-wavelength and/or multi-color) imaging. Multifocal imaging creates multiple corresponding focus positions on a substrate. The present method(s) and apparatus(es) are configured to add and/or otherwise place, based on the multiple (e.g., two or more) different focus positions, one or more assist features to a design layout pattern in one or more locations proximate to one or more of target features of a design layout pattern. The present method(s) and apparatus(es) are also configured to shift a patterning device pattern and/or the deign layout relative to the substrate. The added one or more assist features and the shifting are configured to enhance the target features eventually patterned on the substrate.

Generally, a slit may be an opening, orifice, and/or other radiation passing structure configured to allow radiation from a radiation source to pass. The term slit may be and/or refer to a physical exposure slit (e.g., of a scanner), different slit positions created by means of blading (for example), an exposure tool with multiple physical slits, and/or other slits.

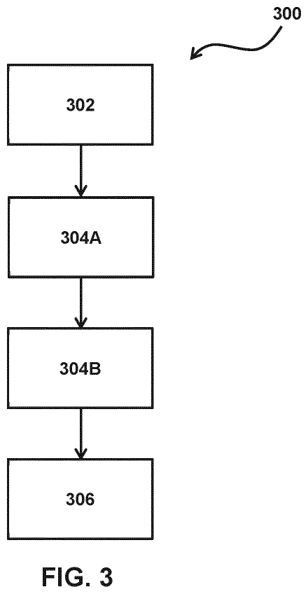

FIG. 3 illustrates an example method 300 for enhancing target features of a design layout pattern imaged (patterned) onto a substrate. Method 300 may be associated with a multifocal lithographic imaging apparatus, for example, and/or other systems. Multifocal lithographic imaging comprises patterning a design layout (e.g., using a patterning device pattern generated based on the design layout) into a substrate with radiation having two or more different wavelengths, which create two or more different focus positions in the substrate. Method 300 comprises determining 302 the two or more different focus positions on the substrate for imaging radiation; adding 304A, based on the two or more different focus positions, one or more assist features to the design layout and/or a patterning device pattern in one or more locations proximate to one or more target features; shifting 304B the patterning device pattern and/or the design layout (e.g., circuit design) based on the two or more different focus positions and the one or more added assist features, causing 306 the target features to be imaged onto the substrate based on the one or more added assist features and the target features; and/or other operations. The added one or more assist features and the shifting are configured to enhance the target features in the substrate. The one or more added assist features and the shifted patterning device pattern and/or design layout are configured to enhance the one or more target features in the substrate by improving one or both of a symmetry of the one or more target features, or placement of the one or more target features, in the substrate, for example. In some embodiments, a pattern comprises a patterning device (e.g., mask) pattern, a design layout, and/or other patterns. In some embodiments, a patterning device pattern may be generated based on a design layout, for example. In some embodiments, method 300 is performed for (or as part of) a semiconductor manufacturing process. In some embodiments, one or more of these operations may be performed via simulation with an electronic model, and/or in other ways. For example, adding the one or more assist features and the shifting may be performed as part of a computational optimization of a multifocal imaging process flow, as described herein.

The operations of method 300 presented below are intended to be illustrative. In some embodiments, method 300 may be accomplished with one or more additional operations not described, and/or without one or more of the operations discussed. For example, method 300 may not require causing 306 the target features of the pattern to be imaged onto the substrate. Additionally, the order in which the operations of method 300 are illustrated in FIG. 3 and described below is not intended to be limiting. For example, an electronic model may perform some or all of the steps of method 300 in sequence, in parallel, and/or substantially simultaneously.

In some embodiments, one or more portions of method 300 may be implemented (e.g., by simulation, modeling, etc.) in one or more processing devices (e.g., one or more processors). The one or more processing devices may include one or more devices executing some or all of the operations of method 300 in response to instructions stored electronically on an electronic storage medium. The one or more processing devices may include one or more devices configured through hardware, firmware, and/or software to be specifically designed for execution of one or more of the operations of method 300, for example.

In some embodiments, determining 302 the two or more different focus positions includes determining presence of, and/or recognizing existence of, two or more focus positions. This may be done, for example, without determining any numerical value associated with, or spatial position of, the focus positions. In some embodiments, determining 302 the two or more different focus positions may include receiving an indication of multifocal imaging from an external device (e.g., a multifocal lithographic imaging device, a computer modeling a prior manufacturing operation, etc.), from entries and/or selections made by a user via a user interface (e.g., as described below), and/or from other sources. In some embodiments, determining 302 the two or more different focus positions may include detecting of radiation of two or more wavelengths from a radiation source, electronically modeling the radiation of two or more wavelengths from the radiation source, and/or other determinations. In some embodiments, determining 302 the two or more different focus positions may comprise using imaging radiation (e.g., in an electronic model and/or in a physical imaging process) having two or more different wavelengths to create two or more different focus positions in on the substrate.

In some embodiments, the two or more different focus positions on the substrate are for imaging radiation having two or more different wavelengths, and are determined for a single exposure of the substrate to the imaging radiation. In some embodiments, the imaging radiation comprises two or more different colors that correspond to the two or more different wavelengths. In some embodiments, the two or more different focus positions are determined based on the two or more different wavelengths of imaging radiation. Multifocal imaging (e.g., imaging using radiation having two or more different wavelengths that creases two or more different focus positions in a layer) is further described in U.S. Patent Application No. 62/747,951, which is incorporated herein by reference in its entirety.

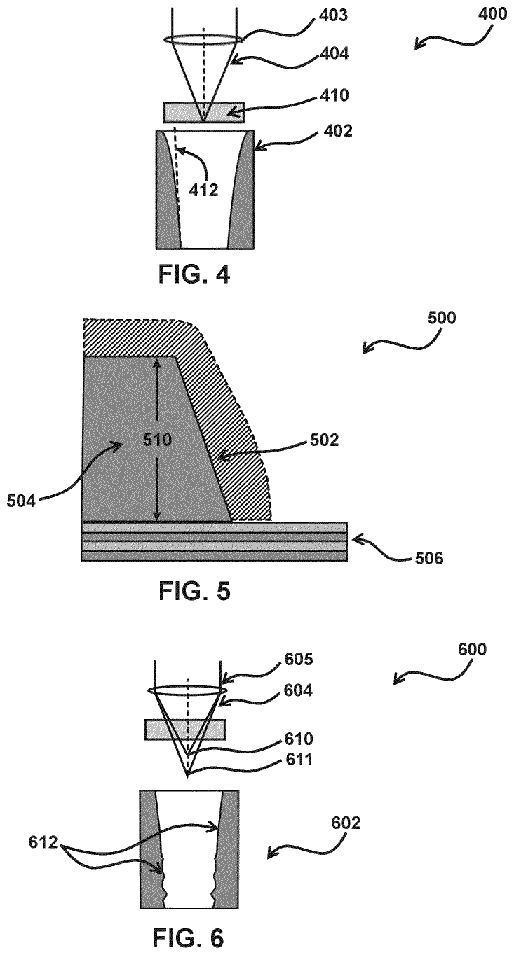

By way of a non-limiting example, FIG. 4 illustrates single focal imaging 400 (e.g., imaging with radiation of a single wavelength or color) for a thick layer 402 of photoresist (as one example). Single focal imaging 400 focuses radiation 404 (e.g., having a given dose and/or other characteristics) with a lens 405 at a single focus position 410 in layer 402. As shown in FIG. 4, single focal imaging 400 may result in features with non-linear sidewalls 412, cause reduced manufacturing productivity due to film thickness limitations and/or reduced etch and trip steps, and/or have other effects. For example, to accommodate effects of single focal imaging 400, the thickness of a given layer may be limited in an effort to maintain a linear sidewall angle. This may limit subsequent etch and/or trimming steps (and/or require subsequent etch and/or trimming steps with specific limited parameters), because there is less available material to etch away, for example.

FIG. 5 illustrates using an additional etch process 500 to improve sidewall angle uniformity and linearity 502 for a feature 504 of a pattern formed on a substrate 506 using single focal imaging 400 (FIG. 4). FIG. 5 illustrates how (e.g., because of the reduced layer thickness described above) a usable (e.g., photoresist) layer thickness 510 and therefore number of possible trim/etch steps is reduced.

In contrast with FIGS. 4 and 5, FIG. 6 illustrates multifocal imaging 600 (e.g., imaging with radiation of two or more wavelengths or colors) for a thick layer 602 of photoresist (as one example). Multifocal imaging 600 focuses radiation 604 (e.g., having a given dose and/or other characteristics) with a lens 605 at two focus positions 610 and 611 in layer 602. As shown in FIG. 6, multifocal imaging 600 facilitates improvement in sidewall angle linearity 612 (e.g., without an etch process), enables more etch/trim operations per each individual lithography step, facilitates the use of thicker photoresist layers, and/or has other effects.

Multifocal imaging has these and other advantages over single focal imaging. However, as described above, (e.g., aerial) image shift occurs across a slit in multifocal imaging. The image shift may have detrimental effects on fabricated devices (e.g., change in resist profile, misalignment between features, misshapen features, etc.) and/or manufacturing operations (e.g., loss of exposure latitude, etc.). The impact or amount of the shift is dependent on the differences between the two or more wavelengths used in the multifocal imaging.

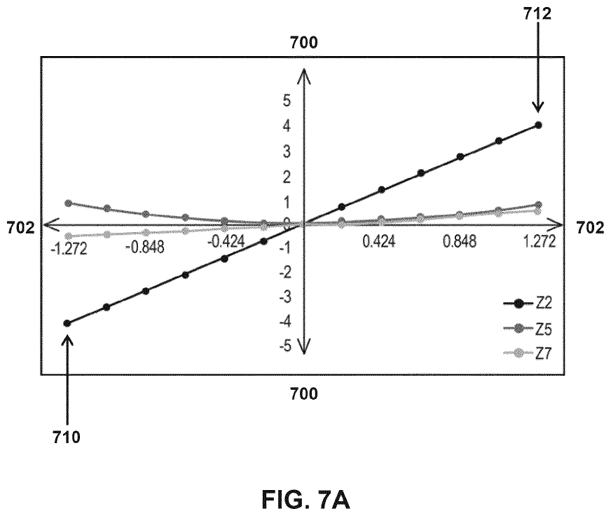

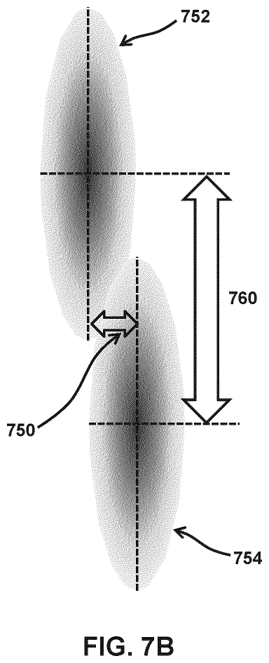

FIG. 7A illustrates an example of image shift 700 across different slit positions 702 for a slit in a multifocal lithographic imaging apparatus. The image shift shown in FIG. 7A is associated with a KrF lens (e.g., lenses 405 and 605 shown in FIG. 4 and FIG. 6), but this is not intended to be limiting. In the KrF lens example shown in FIG. 7A, image shift occurs across the slit and the impact is dependent on the amount of difference between the two wavelengths (used in this example multifocal imaging process). The image shift may be associated with one or more collateral Zernike polynomials associated with the lens and/or other optical components. Zernike polynomials are a sequence of polynomials that are orthogonal on the unit disk. They are useful in expressing wavefront data since they are of the same form as the types Zernike Polynomials of aberrations often observed in optical tests. (Ref: Born, Max, and Wolf, Emil (1999). Principles of Optics: Electromagnetic Theory of Propagation, Interference and Diffraction of Light (7th ed.). Cambridge, UK: Cambridge University Press. p. 986. ISBN 9780521642224). In this example, image shift 700 occurs across the slit and is associated with Zernike polynomial Z2. As shown in FIG. 7A, the impact of Z2 is more severe at the edges 710, 712 of the slit (and Z2 changes sign negative to positive from edge 710 to edge 712 across the imaging field). This example is not intended to be limiting. This effect may occur with (and the method(s) and apparatus(es) described herein may be configured to correct for) other lenses such as lower k1 KrF, ArF, ArF immersion lenses, for example, and/or image shift associated with other Zernike polynomials (e.g., Z5, Z7, etc.).

Continuing with this example, FIG. 7B illustrates a shift 750 associated with different (e.g., aerial) images 752 and 754 that correspond to the two different wavelengths of radiation used for the multifocal imaging in this example. Focus shift 760 was introduced (e.g., because a multifocal imaging process was used) to improve a depth of focus, which can facilitate improvement in sidewall angle linearity (e.g., without an etch process), enable more etch/trim operations per each individual lithography step, facilitate the use of thicker photoresist layers, and/or has other effects as described above. However, when multifocal imaging is used, shift 750 may be caused by collateral Zernike polynomials (e.g., such as Z2) as described above. This may cause a loss of exposure latitude, a change in resist profile, and/or have other effects.

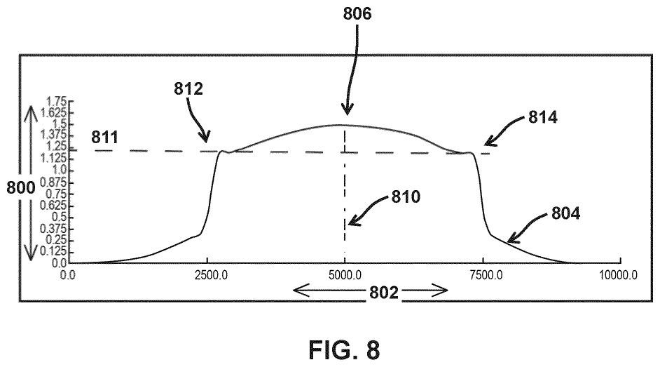

Image shift associated with multifocal imaging is present in aerial images. For example, FIG. 8 illustrates an intensity 800 versus mask position 802 plot 804 for a portion of an aerial image associated with a pattern target feature 806. Plot 804 was generated using (or based on) a single focal imaging process. Plot 804 is generally symmetrical about a (hypothetical) centerline 810 of target feature 806. For example, plot 804 has generally the same shape at the same intensity 811 on either side 812, 814 of target feature 806.

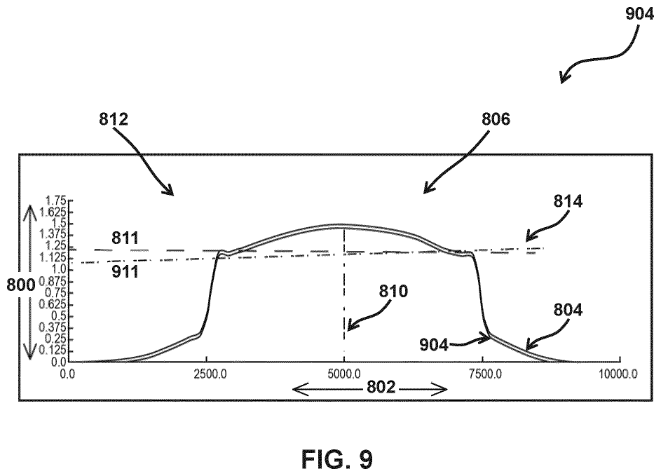

In contrast, FIG. 9 illustrates a different intensity 800 versus mask position 802 plot 904 shown relative to plot 804 for the portion of the aerial image associated with pattern target feature 806. Plot 904 was generated using (or based on) a multifocal imaging process. Plot 904 is not generally symmetrical about (hypothetical) centerline 810 of target feature 806. For example, plot 904 has a generally lower intensity on side 812 compared to side 814 of target feature 806 (resulting in tilted line 911 compared to the generally horizontal line indicating intensity 811). The tilt on the left side of plot 904 is due to the image shift and asymmetry caused by the separation between the (two or more) different wavelengths used in multifocal imaging (e.g., caused by Z2) relative to plot 804 in FIG. 9.

One or more assist features may be added to a design layout and/or patterning device pattern (e.g., operation 304A shown in FIG. 3) to compensate and/or otherwise adjust for the image shift described above. Adding may include placing, and/or other adding operations, for example. In some embodiments, adding (e.g., 304 shown in FIG. 3) the one or more assist features comprises adjusting a base or initial pattern comprising the target features (e.g., target feature 806) to include the one or more assist features. The one or more assist features are added in one or more locations proximate and/adjacent to one or more of the target features. Proximate and/or adjacent to may be and/or include touching, almost touching, a small distance from, and/or other spacings. Proximate and/or adjacent may refer to any spacing configured to allow the added one or more assist features to function as described herein. The one or more assist features may be placed and/or otherwise added into a design layout and/or a patterning device pattern asymmetrically (e.g., to one side of a target feature), symmetrically (e.g., individual assist features on opposite sides of a target feature), and/or in other orientations. In some embodiments, placing/adding the one or more assist features to the pattern in the one or more locations proximate to the one or more target features of the pattern comprises electronically modeling the one or more assist features in the pattern. Adding the one or more assist features is based on the two or more different focus positions and/or other information.

In some embodiments, the target features (e.g., 806) may be components of a device (e.g., a semiconductor device) that a designer intends to print on the substrate (e.g., and become part of a final device so the device functions as intended). The assist features may comprise features in addition to the target features that need not be printed and/or become part of the final device. Assist features may be placed/added to assist manufacturing of the target features, for example. In some embodiments, the one or more assist features comprise one or more sub-resolution assist features, and/or other features. In some embodiments, the added one or more assist features are configured to enhance the target features on the substrate by improving one or both of a symmetry of the target features of the pattern, or placement of the target features of the pattern, in the substrate.

Placing/adding the one or more assist features to the pattern enhances the target features by reducing an imaging field shift (e.g., the shift described above). For example, in some embodiments, placing/adding the one or more assist features to the design layout and/or the patterning device pattern enhances the target features by reducing a shift caused by across slit asymmetry for a slit of a multifocal lithographic imaging apparatus. In some embodiments, the across slit asymmetry is associated with collateral Zernike polynomials (e.g., as described above). In some embodiments, the across slit asymmetry is associated with a Z2 Zernike polynomial, for example (also as described above).

In some embodiments, different ones of the one or more assist features correspond to (an amount of shift for) one or more different slit positions in the slit. In some embodiments, placing/adding the one or more assist features in the one or more locations proximate to the one or more target features comprises determining a shape, a size, a position, and/or an orientation of the one or more assist features relative to the one or more target features. The shape, size, position, and/or orientation of an assist feature is determined based on a corresponding slit position for a given feature, the (e.g., geometry) of the target feature itself, and/or other information, for example. In some embodiments, placing/adding the one or more assist features to the pattern in one or more locations proximate to one or more target features of the pattern comprises adding one assist feature on one side of a given target feature. For example, a single sided assist feature may be added depending on the corresponding slit position. A different assist feature or features (e.g., a double sided assist feature) may be added for a different corresponding slit position.

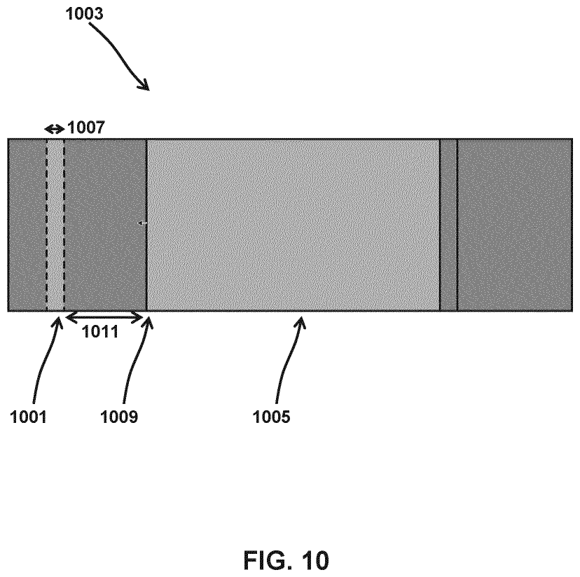

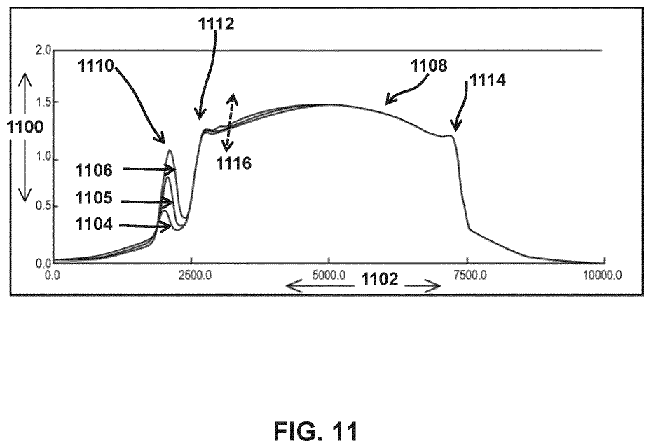

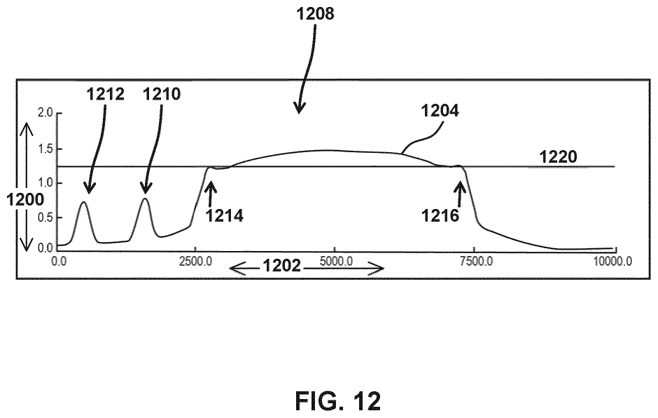

By way of a non-limiting example, FIG. 10 illustrates an assist feature 1001 added to a pattern 1003 (e.g., a design layout and/or a patterning device pattern). As described above, assist feature 1001 is added to pattern 1003 to compensate and/or otherwise adjust for image shift that occurs as the result of the two focus positions in multifocal imaging (e.g., see focus positions 610 and 611 described above related to FIG. 6). Pattern 1003 comprises target feature 1005. In this example, assist feature 1001 comprises a line added on one side of (adjacent to) target feature 1005. Assist feature 1001 corresponds to a slit position in a slit. Corresponding to a slit position in a slit may refer to being designed to compensate and/or otherwise adjust for a given amount of image shift associated with that slit position, for example. The shape, size, position, and orientation of assist feature 1001 is determined relative to target feature 1005. The shape, size, position, and orientation of assist feature 1001 is determined based on the corresponding slit position, the geometry of target feature 1005, and/or other information, for example. Here, assist feature 1001 is a line that runs parallel to an edge 1009 of target feature 1005. Assist feature 1001 has a width 1007 and is positioned at a given distance 1011 from edge 1009. Adding, based on the two or more different focus positions (e.g., 610 and 611), assist feature 1001 to pattern 1003 in one or more locations proximate to target feature 1005 of pattern 1003 is configured to enhance target feature 1005 (e.g., make a sidewall angle more linear as described herein and/or other enhancements) on the substrate. This occurs because the addition of assist feature 1001 proximate to target feature 1005 reduces the shift (caused by focus positions 610 and 611) in an (e.g., aerial) image of feature 1005 (e.g., as shown in FIG. 11-12 described below). This assist feature shape, size, position, and orientation is just an example. Other assist feature shapes, sizes, positions, and orientations are contemplated.

By way of another non-limiting example, FIG. 11 illustrates a series of intensity 1100 versus mask position 1102 plots 1104, 1105, and 1106 for a portion of an aerial image associated with a target feature 1108 and an assist feature 1110. In this example, assist feature 1110 is approximately 3000 nm from the center of target feature 1108. Plots 1104-1106 were generated using (or based on) a multifocal imaging process. Plots 1104-1106 reflect a changing shape, size, position, and/or orientation of assist feature 1110 (relative to target feature 1108). As the shape, size, position, and/or orientation of assist feature 1110 is changed (e.g., determined or re-determined based on the corresponding slit position, the geometry of target feature 1108, and/or other information), the generally different intensity on side 1112 compared to side 1114 of target feature 1108 is increased or decreased 1116 to match the intensity on side 1114. In other words, the tilt on the left side of target feature 1108 due to the image shift caused by the separation between the (two or more) different wavelengths used in multifocal imaging is decreased. Thus, added assist feature 1110 enhanced target feature 1108 on the substrate by improving the symmetry of target feature 1108, for example. Adding assist feature 1110 to the pattern enhanced target feature 1108 by reducing an imaging field shift (e.g., a shift caused by across slit asymmetry for a slit of a multifocal lithographic imaging apparatus). It should be noted that the shape, size, position, and/or orientation of assist feature 1110 need not be determined multiple times as shown in FIG. 11. This was merely an example used to show the effect of assist feature 1110 on target feature 1108.

In some embodiments, adding one or more assist features to the pattern in one or more locations proximate to one or more target features of the pattern comprises adding at least one assist feature on each of two or more different sides of a given target feature. In some embodiments, adding one or more assist features to the pattern in one or more locations proximate to one or more target features of the pattern comprises adding two or more assist features on one side of a given target feature.

For example, FIG. 12 illustrates an intensity 1200 versus mask position 1202 plot 1204 for a portion of an aerial image associated with a target feature 1208 and two assist features 1210 and 1212. Plot 1204 was generated using (or based on) a multifocal imaging process. Plot 1204 reflects how two separate assist features 1210 and 1212 added to one side of target feature 1208 facilitate a generally similar intensity 1220 on sides 1214 and 1216 of target feature 1208. In other words, any tilt on the left side of target feature 1208 due to the image shift caused by the separation between the (two or more) different wavelengths used in multifocal imaging is decreased or eliminated. Thus, added assist features 1210 and 1212 enhanced target feature 1208 on the substrate by improving the symmetry of target feature 1208, for example. Adding assist features 1210 and 1212 to the pattern enhanced target feature 1208 by reducing an imaging field shift (e.g., a shift caused by across slit asymmetry for a slit of a multifocal lithographic imaging apparatus). It should be noted that the two assist features were used as an example only. Other examples are contemplated.

Returning to FIG. 3, in some embodiments, adding 304A the one or more assist features comprises determining (which may be part of electronically modelling) an image associated with the substrate. In some embodiments, the image is an aerial image, an intensity versus mask position plot, and/or other images. For example, operation 304 shown in FIG. 3 may include determining, modelling, and/or otherwise generating an aerial image and/or an intensity versus mask position plot as described above. The aerial image may be determined by adding the one or more assist features to the pattern in the one or more locations proximate to one or more of the target features; and determining the image based on the one or more added assist features and the target features. Determining the image may include generating an electronic model of the image, determining a physical image, determining a feature image intensity profile for one or more of the target features, and/or other image generation operations. In some embodiments, determining the image based on the one or more added assist features and the one or more target features improves one or both of a symmetry of the target features of the pattern, or placement of the target features of the pattern, in the image (and/or electronic model), as described above (e.g., related to FIGS. 8-12).

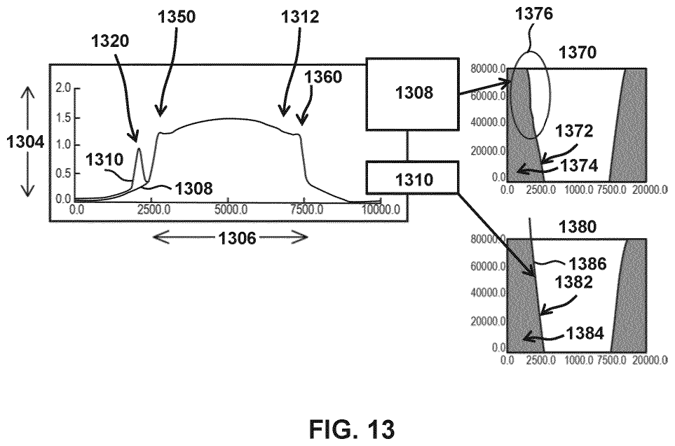

In some embodiments, one or both of the symmetry of the target features of the pattern, or the placement of the target features of the pattern (e.g., in an image and/or eventually an actual device) are improved relative to a symmetry and/or placement of target features (e.g., in a different image and/or an actual device) determined (e.g., manufactured) without considering the added assist features. For example, FIG. 13 illustrates the effect of adding an assist feature 1300 proximate to a target feature 1302 in a pattern on a resist profile.

FIG. 13 illustrates two different intensity 1304 versus mask position 1306 plots 1308 and 1310 for a portion of an aerial image associated with a pattern target feature 1312. Plots 1308 and 1310 were generated using (or based on) a multifocal imaging process. Plot 1308 was generated before assist feature 1320 was added to the pattern, and plot 1310 was generated after assist feature 1320 was added to the pattern. Plot 1308 is not generally symmetrical about a centerline of target feature 1312. For example, plot 1308 has a generally different intensity on side 1350 compared to side 1360 of target feature 1312. The tilt (note the separation between lines) on the left side of plot 1308 is due to the image shift caused by the separation between the (two or more) different wavelengths used in multifocal imaging. However, this same tilt is not present (or is at least reduced) in plot 1310, which was generated after assist feature 1320 was added to the pattern.

FIG. 13 illustrates resist profiles 1370 and 1380 that correspond to plots 1308 and 1310 respectively. In resist profile 1370 (which corresponds to plot 1308 generated before assist feature 1320 was added to the pattern), the sidewall 1372 of a feature 1374 is non-linear in one or more areas 1376. In resist profile 1380 (which corresponds to plot 1310 generated after assist feature 1320 was added to the pattern), the sidewall 1382 of a feature 1384 is more linear 1386 (relative to areas 1376).

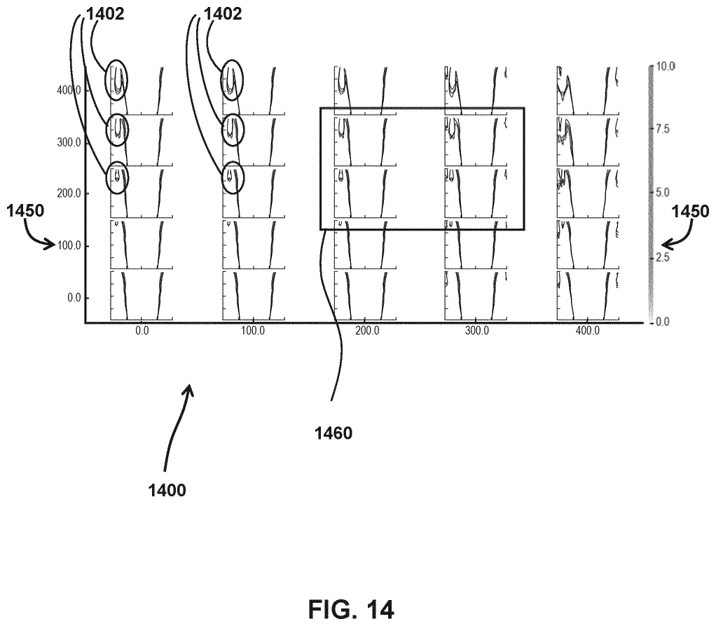

In some embodiments, a shape, size, position, and/or orientation of the one or more assist features are configured such that the one or more assist features are not formed on the substrate. For example, FIG. 14 illustrates various example resist profiles 1400 generated (e.g., modeled) based on different added assist features 1402. The added assist features have different shapes, sizes, positions, orientations, etc. As shown in FIG. 14, the shapes, sizes, positions, orientations, etc. of assist features 1402 may be varied to a point 1450 assist features 1402 disappear from resist profiles 1400. However, the present system(s) and method(s) may be configured such that the shapes, sizes, positions, orientations, etc. are still sufficient to produce a linear sidewall angle and/or other desired characteristics in one or more features patterned onto a substrate. FIG. 14 illustrates an example set 1460 of resist profiles 1400 where the shapes, sizes, positions, orientations, etc. of the assist features disappear from resist profiles 1400, but are still sufficient to produce a linear sidewall angle and/or other desired characteristics in one or more features patterned onto a substrate.

Returning to FIG. 3, at operation 304B, the patterning device pattern and/or a design layout pattern are shifted based on the two or more different focus positions and the one or more placed/added assist features. The shifting may be relative to each other, relative to the substrate, and/or relative to other references. The design layout may include a circuit design, and/or other design layouts, for example. The one or more placed/added assist features in combination with the shifted patterning device pattern and/or design layout are configured to further enhance the one or more target features in the substrate. The enhancing is achieved by reducing a shift that would otherwise be caused by across slit asymmetry for a slit through which imaging radiation passes during imaging of the substrate. In other words, placing/adding the one or more assist features to the patterning device pattern and shifting the patterning device pattern and/or the circuit design enhances the one or more target features by reducing the shift caused by across slit asymmetry for a slit of a multifocal lithographic imaging apparatus. For example, if the one or more target features have sidewalls, adding the one or more assist features and shifting the patterning device pattern are performed to achieve a required sidewall angle, side wall angle linearity, side wall angle symmetry, and/or other criteria.

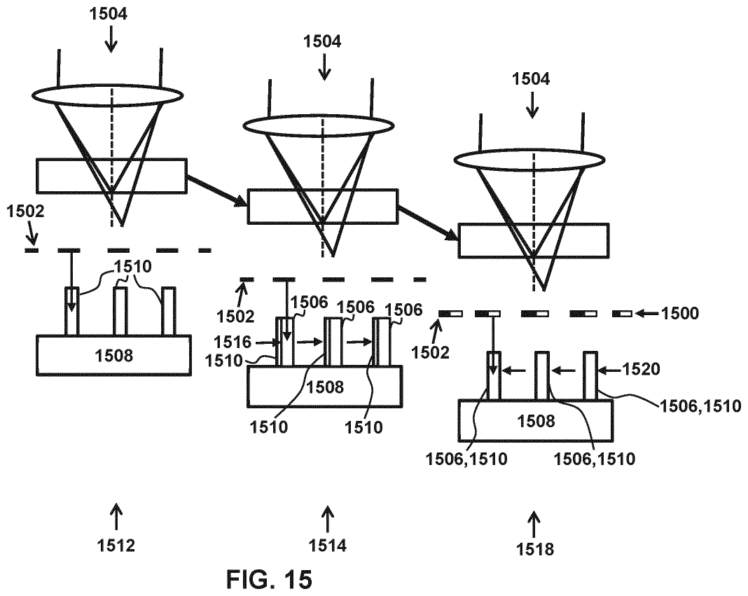

By way of a non-limiting example, FIG. 15 illustrates shifting 1500 the patterning device pattern and/or a design layout based on the two or more different focus positions and the one or more added assist features. Shifting 1500 the patterning device pattern and/or a design layout may be necessary because of the (e.g., aerial) image shift described above caused by multi-focal imaging. The image shift distance may be dependent on the wavelength separation of the imaging radiation used, slit position, and/or other factors as described herein. The example in FIG. 15 illustrates a KrF multifocal imaging arrangement 1504 (see FIGS. 4-6), and shows the shifting 1500 of a mask 1502 to compensate for the image shift. Mask 1502 is shifted 1500 so that features 1506 patterned on a substrate 1508 are in their desired locations 1510. A first view 1512 in FIG. 15 illustrates desired locations 1510 relative to mask 1502. A second view 1514 illustrates the shift 1516 caused by multifocal imaging. A third view 1518 illustrates features 1506 in desired locations 1510 as a result of shifting 1500 mask 1502. The amount 1520 of the mask 1502 shift 1500 is predictable (e.g., Z2 thru slit is measured). Amount 1520 may be determined with a rule based and/or other models, and/or using other operations. For example, an ASML Tachyon rule based model may be used. Shifting 1500 can be achieved with mask feature repositioning, physical movement of the mask, movement of desired locations 1510 (e.g., changing the design layout or circuit design), and or other operations.

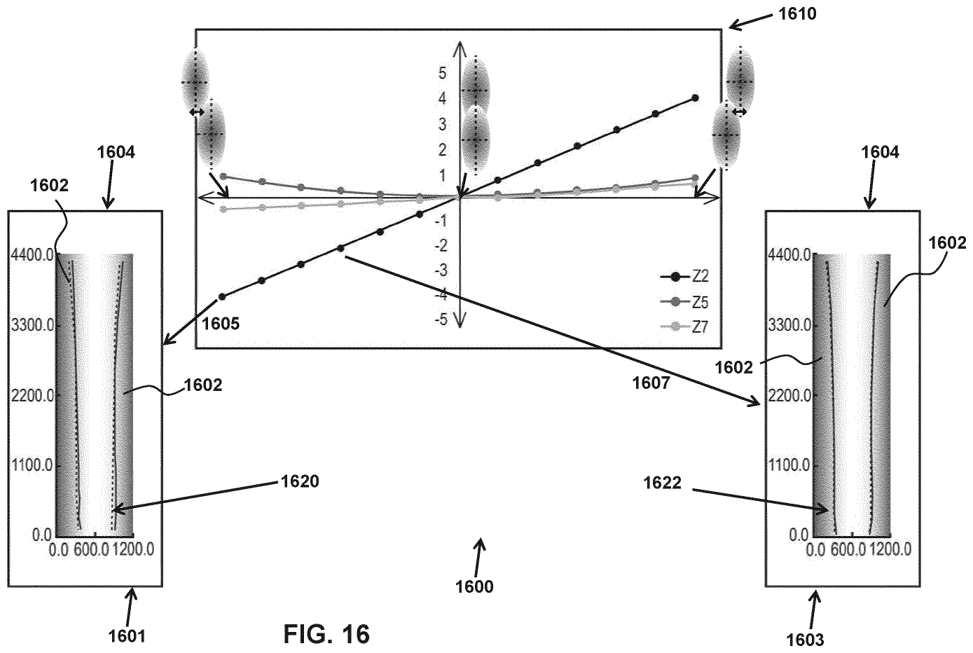

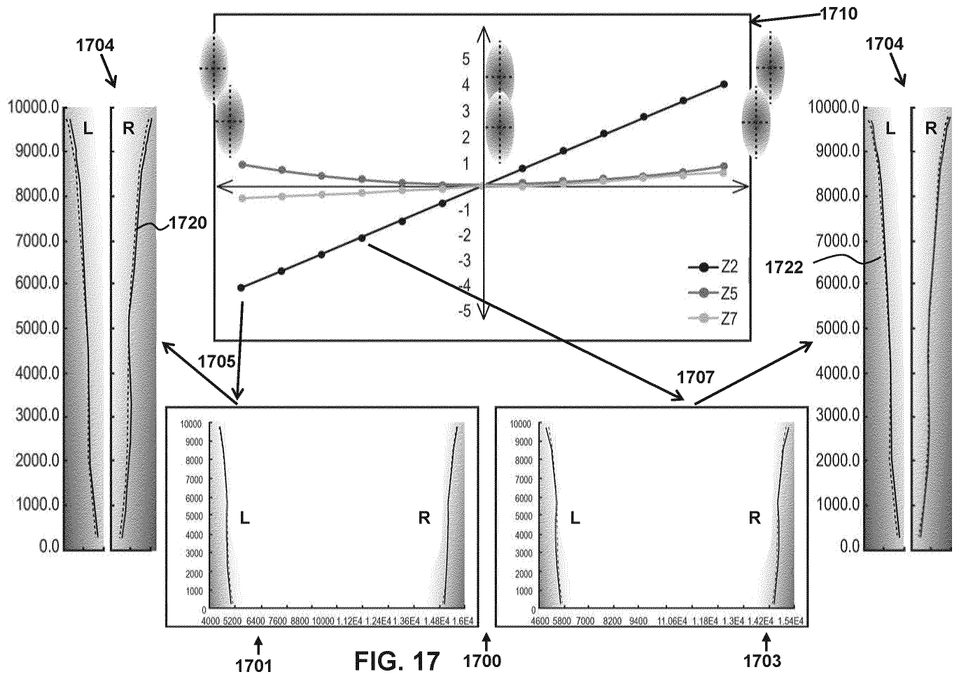

Based on the known Zernikes and known chromatic aberrations, as well as the required placement of a resulting image and/or other factors, patterning device pattern features (e.g., the actual Cr on a mask) and/or a design layout (e.g., a GDS file) can be shifted to compensate for the (aerial) image shift from a multifocal (e.g., wavelength) imaging system to achieve the desired location on the wafer. This shift can be determined using OPC tools (e.g., ASML Tachyon OPC+, SMO) and modeled. For example, FIG. 16 illustrates a first example of images 1601, 1603 of a model 1600 of sidewalls 1602 of a pattern target feature 1604. FIG. 16 illustrates KrF chromatic aberrations changing 1610 across a slit. Images 1601 and 1603 correspond to different slit positions 1605 and 1607. As described herein, the amount of the shift changes with slit position 1605, 1607. FIG. 16 is for a 0.3 um trench on a 1.2 um pitch (space feature demonstrating expected shift based on known Z2 contribution). This shift is predictable and measurable for a KrF wavelength separation of 15 μm (used in this example). For slit position 1605, the shift 1620 (exaggerated for easier viewing in FIG. 16) is about 37 nm. For slit position 1607, the shift 1622 (exaggerated for easier viewing in FIG. 16) is about 18 nm. This example is based on known use cases for thick photoresist applications in image sensors (e.g., 0.55NA, 4.4 um of photoresist (+ve tone).

FIG. 17 illustrates a second example of images of a model of sidewalls of a shifted pattern target feature, according to an embodiment. In FIG. 17, images for a 10 um trench on a 20 um pitch (space feature demonstrating expected shift based on known Z2 contribution) are shown. This shift is predictable and measurable for a KrF wavelength separation of 15 μm (e.g., as used in this example). This example is based on known use cases for thick photoresist applications in 3D NAND staircase applications. (In digital electronics, a NAND gate (NOT-AND) is a logic gate which produces an output which is false only if all its inputs are true.) FIG. 17 illustrates images 1701, 1703 of a model 1700 of sidewalls 1602 (left (L) and right (R)) of a pattern feature 1704. FIG. 17 illustrates KrF chromatic aberrations changing 1710 across a slit. Images 1701 and 1703 shown enlargements and correspond to different slit positions 1705 and 1707. As described herein, the amount of the shift changes with slit position 1705, 1707. For slit position 1705, the shift 1720 (exaggerated for easier viewing in FIG. 17) is about 77 nm. For slit position 1707, the shift 1722 (exaggerated for easier viewing in FIG. 17) is about 18 nm.

Returning to FIG. 3, causing 306 the target features of the pattern to be imaged onto the substrate based on the one or more added assist features and the target features may include causing the target features of the pattern to be imaged onto the substrate based on the aerial image (or model of the aerial image), and/or some other form of the adjusted pattern, having the added assist features described above. Operation 306 may include determining process rules, electronically modeling portions of a manufacturing process, physically performing additional portions of a manufacturing process, and/or other activities. For example, operation 306 and/or other operations of method 300 may comprise electromagnetic modelling, scalar modelling, and/or other types of modelling. In some embodiments, operation 306, alone and/or in combination with one or more of operations 302, 304A, and 304B may comprise a computational optimization of a multifocal imaging process flow.

In some embodiments, operations 302, 304A, 304B, and/or 306 comprise determining through slit assist feature rules and placing the one or more assist features based on the optimized added assist features, and applying a full field optical proximity correction for the patterning device pattern. The full field optical proximity correction may be model based or rules based. Applying the full field optical proximity correction comprises: applying, based on the shifted patterning device pattern and/or circuit design, a through slit repositioning shift to the one or more target features of the patterning device pattern; applying the optimized through slit added assist features; and applying a main feature bias. In some embodiments, operation 306, alone or in combination with adding the one or more assist features (operation 304A) and shifting the patterning device pattern and/or the design layout (operation 304B) comprises adjusting a numerical aperture (NA), a sigma (e.g., a partial coherence factor=(condenser lens NA_{c}/projection lens NAₚ)), a best focus (described below), and/or a wavelength peak separation (described below) associated with imaging radiation to optimize the one or more added assist features such that shifting the patterning device pattern and/or the circuit design is based on one or more optimized added assist features. This optimization comprises through slit optimization.

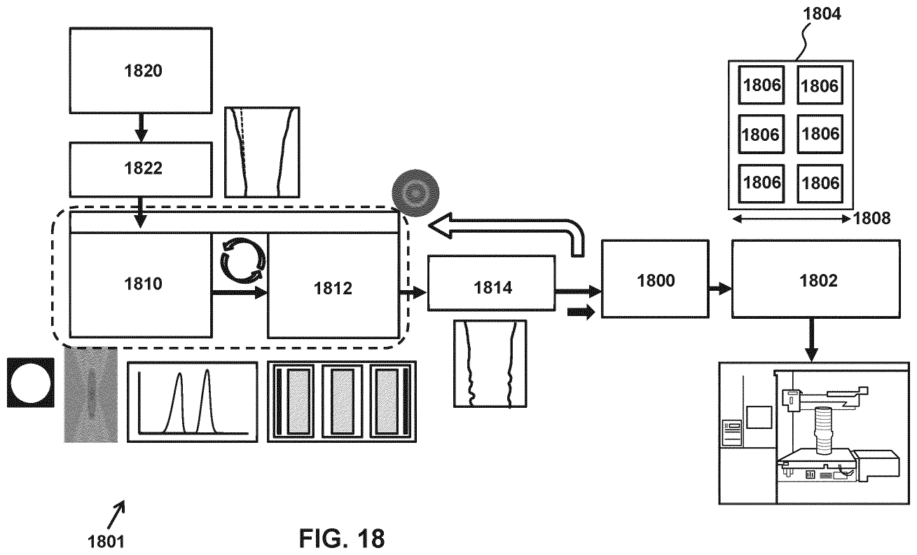

By way of a non-limiting example, FIG. 18 illustrates flow 1801 comprising determining 1800 through slit assist feature and pattern shift rules and placing the one or more assist features based on the optimized added assist features, and applying 1802 a full field 1804 (comprising various cells 1806) optical proximity correction for the patterning device pattern across a slit 1808. Full field optical proximity correction may be model based or rules based. Applying 1802 the full field optical proximity correction comprises: applying, based on the shifted patterning device pattern and/or circuit design, a through slit repositioning shift to the one or more target features of the patterning device pattern; applying the optimized through slit added assist features; and applying a main feature bias.

In some embodiments, flow 1801 comprises adjusting and/or otherwise tuning 1810 a numerical aperture (NA), a sigma, a best focus, and/or a wavelength peak separation associated with imaging radiation to optimize 1812 the one or more added assist features such that shifting the patterning device pattern and/or the circuit design is based on one or more optimized added assist features. In this example, the target features have sidewalls. Flow 1801 may include a determination 1814 of whether sidewall angle and linearity through slit, image placement, and/or other parameters meet specification after optimization 1812 (and repeat the optimization as necessary). Flow 1801 may begin, for example, with generation 1820 of a calibrated electronic model configured to predict a resist 3D profile, and/or an initial check 1822 of sidewall angle and/or linearity.

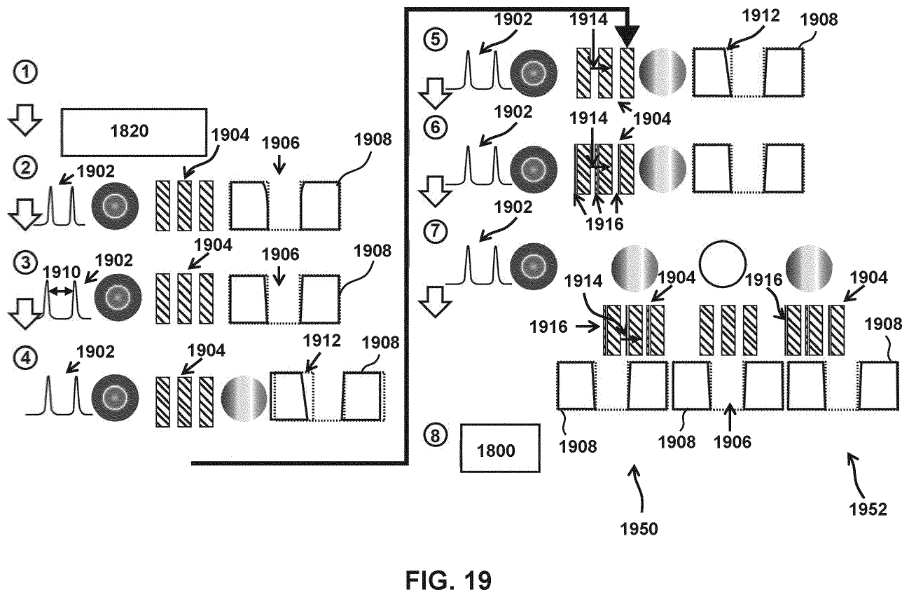

FIG. 19 provides further detail about the operations of flow 1801 shown in FIG. 18. FIG. 19 illustrates steps 1-8. Steps 1-8 may be and/or include simulations, for example, and/or may be performed in other ways. Step 1 comprises generation 1820 of the calibrated electronic model configured to predict the resist 3D profile. Step 2 comprises simulation of a baseline multifocal imaging setup. Illustrations of a peak wavelength separation 1902, pattern features 1904, and a center slit cross sectional image 1906 of a pattern feature 1908 are shown at Step 2. Step 3 illustrates determining 1910 a multifocal imaging peak wavelength separation and best focus tuning for sidewall angle (in this example) optimization. Step 4 illustrates an evaluation of multifocal imaging with a chromatic aberration (e.g., determining across slit variation for Z2 and all Zi). Step 4 illustrates a different sidewall angle 1912 for a position at the edge of a slit compared to the side wall angles shown in center slit cross sectional images 1906. Step 5 illustrates determination 1914 of a multifocal imaging patterning device (e.g., mask) pattern shift. Step 6 illustrates determination and placement of one or more assist features 1916. In this example, the assist features are asymmetric (e.g., are placed only on one side of features 1904). Steps 5 and 6, along with one or more of the other steps may be completed to compensate and/or correct for the across slit variation described herein. It should be noted that steps 5 and 6 may be completed in any order (e.g., step 5 then step 6 or step 6 then step 5) and/or substantially simultaneously. Step 7 illustrates through slit patterning device (e.g., mask) pattern optimization (e.g., including the shift of step 5 and the assist feature generation of step 6) to achieve better pattern feature side wall angles (in this example). Step 7 illustrates added assist features 1916 and pattern shifts determined 1914 and/or otherwise optimized for positions 1950, 1952 on either side of a slit, as well as a central slit position shown in image 1906. Steps 4-7 may form some or all of operations 1810-1814 shown in FIG. 18, for example. Step 8 illustrates determining 1800 through slit assist feature and pattern shift rules. The rules may be determined to ensure sidewall characteristics, image placement error, and/or other parameters meet specification after addition of the one or more assist features and/or pattern shifting. The rules may be associated with spacing between assist features and target features, image shift amounts for specific wavelength peak separations and numerical apertures, and/or other pattern characteristics.

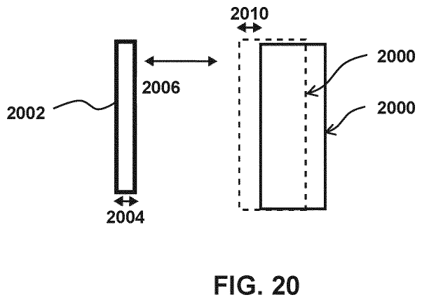

FIG. 20 illustrates an example of an optimized through slit pattern, and assist feature rules. FIG. 20 illustrates a target pattern feature 2000 and an added assist feature 2002. In this example, the optimized through slit pattern comprises target pattern feature 2000 and added assist feature 2002. Assist feature 2002 has a specific width 2004 and separation distance 2006 from target feature 2000. Assist feature 2002 may be determined to be necessary, shaped, and/or placed as described herein (e.g., as part of the through slit optimization). Width 2004, separation distance 2006, and/or other parameters may be determined based on through slit assist feature rules, for example. The rules may be associated with spacing between assist features and target features (e.g., separation distance 2006 between assist feature 2002 and an edge of target feature 2000), an assist feature width (e.g., 2004), image shift amounts for specific wavelength peak separations and numerical apertures (e.g., a reference NA), and/or other pattern characteristics. As shown in FIG. 20, a pattern including target feature 2000 and assist feature 2002 may also need to be shifted 2010 to (e.g., further) compensate for across slit variation and ensure target feature 2000 is positioned as intended in a substrate. These (e.g., shift 2010, width 2004, separation distance 2006) and other parameters may vary (e.g., the rules may dictate differences) for different slit positions.

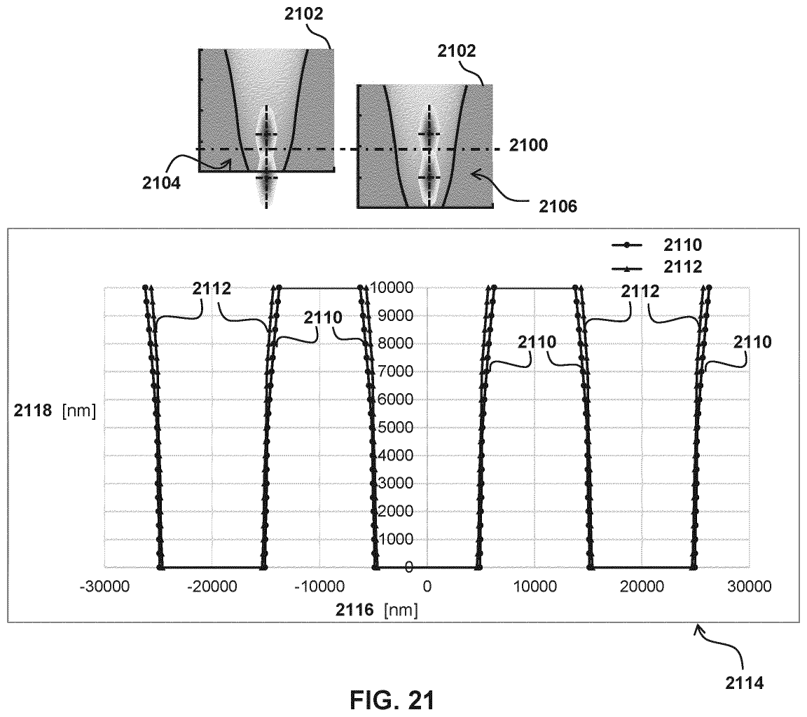

FIG. 21 illustrates an example of optimizing a best focus position 2100 in a resist layer (for example) 2102 for a multifocal imaging process. Optimizing best focus position 2100 may be included in operation 1810 shown in FIG. 18, and/or other operations, for example. Best focus position 2100 may be associated with an aerial image. A best focus position may be a substrate position on a scanner substrate table that achieves highest image contrast, for example. Optimizing best focus position 2100 may comprise repeatedly changing a best focus position in resist layer 2102, and determining corresponding sidewall angles and/or other characteristics of a target feature for different best focus positions. Optimizing the best focus position 2100 may comprise determining and/or otherwise choosing the best focus position that facilitates fabrication of the most consistent (and/or other measures of quality) sidewall angle, linearity, and/or other characteristics of a target feature. In the example shown in FIG. 21, best focus position 2100 was changed from a (e.g., z-direction) location at or near the “bottom” (this term is not intended to be limiting) 2104 of resist layer 2102 (e.g., at an 8 um depth), where a best focus value was −4320.49 nm, to a location at or near a “middle” (this term is not intended to be limiting) 2106 of resist layer 2102 (e.g., at a Sum depth), where the best focus value was −2700.31 nm. In this example, when best focus position 2100 was at the location at the “bottom” of resist layer 2102, where the best focus value was −4320.49 nm, the resulting sidewall angle was 81.84 degrees, with an R-squared value (e.g., a measure of linearity) of 0.8962. When best focus position 2100 was at the “middle” of resist layer 2102, where the best focus value was −2700.31 nm, the resulting sidewall angle was 84.53 degrees (e.g., closer to 90 degrees and/or some other target measurement), with an R-squared value of 0.9208 (e.g., closer to 1.0).

The better (e.g., closer to 90 degree) sidewall angle and linearity (e.g., closer to 1.0) associated with the “middle” best focus position is illustrated in the resist profiles 2110, 2112 shown in the resist profile chart 2114 of FIG. 21. Chart 2114 illustrates wafer position 2116 versus resist height 2118 for a (simulated) resist layer. As shown in chart 2114, resist profile 2112 has a sidewall angle closer to 90 degrees (e.g., 84.53 degrees) and is more linear relative to resist profile 2110. This means, for this example, an optimized best focus position 2100 would be the best focus position corresponding the “middle” best focus position.

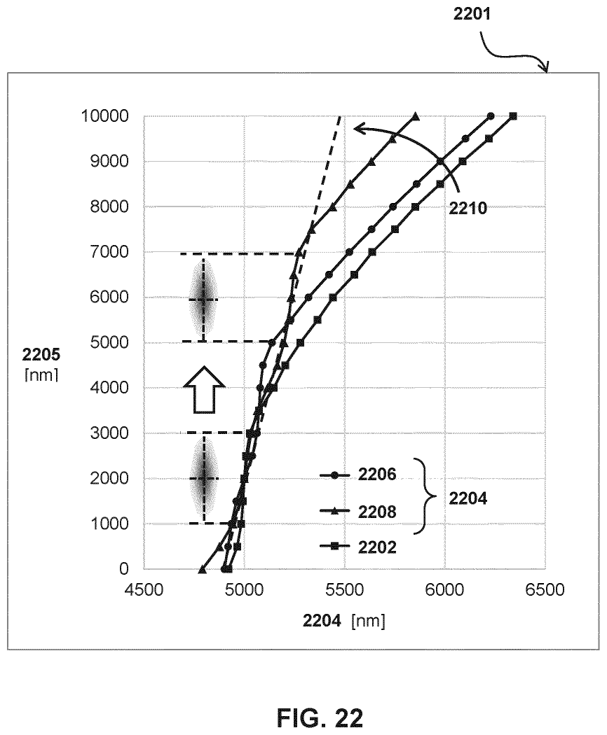

FIG. 22 illustrates adjusting, tuning, and/or otherwise optimizing a wavelength peak separation of multifocal imaging radiation. Adjusting and/or otherwise optimizing the wavelength peak separation may be included in operation 1810 shown in FIG. 18, and/or other operations, for example. FIG. 22 illustrates a resist profile plot 2201 where a substrate position 2203 is plotted along the horizontal axis and resist height 2205 is plotted along the vertical axis. As shown in FIG. 22, changing from single focal imaging 2202 radiation to multifocal 2204, and changing a best focus position for a location at the bottom of a resist layer 2206 to a middle of the resist layer 2208 improves 2210 (e.g., gets closer to an ideal 2212) sidewall (e.g., in sidewall angle and/or linearity). Adjusting, tuning, and/or otherwise optimizing the wavelength peak separation may include varying the wavelength peak separation of the multifocal imaging radiation by itself, and/or varying the wavelength peak separation along with one or more other parameters (e.g., in a design of experiments—DOE—style pattern of variation). For example this may include simulating different middle positions in the resist layer (e.g., a 4 um depth versus a Sum depth versus a 6 um depth), along with different wavelength peak separations (e.g., 15 μm versus 22.5 μm versus 30 μm). These experiments may vary depth (e.g., 4, 5, 6 um depths), wavelength separations (e.g., 15 μm, 22.5 μm, 30 μm), and/or other parameters to find optimal combinations (e.g., combinations that produce desired sidewall angles and linearity). Continuing with the example described above, single focal imaging produces sidewall angle of 81.27 degrees. Multifocal positioned at “bottom” was 81.84 degrees and positioned in “middle” was 84.53 degrees. By varying different middle locations (e.g., 4 um depth to Sum depth) and varying wavelength separation, a 4 um best focus depth with a 15 μm wavelength peak separation may be found to produce a sidewall with 0.99 R-squared linearity (in this example).

In some embodiments, through slit assist feature rules (e.g., as described above) are determined based on a custom cost function. The custom cost function may be used to optimize a patterning device pattern with one or more added assist features to compensate for the shift caused by the Z2 and/or other polynomials. This may include generating an optimal assist feature placement, achieving a target sidewall angle and/or symmetry, generating an assist feature rule table, and/or other operations.

A baseline cost function may be generated for EPE. EPEs may be evaluated through a user defined process window and mask error conditions at a single focus (Z) plane. An optimization minimizes the EPE at a single image plane and cannot control the sidewall angle. In contrast with the baseline cost function, the custom cost function of the present disclosure can target achieving a specific target sidewall angle. Continuing with the target feature sidewall example described herein, the custom cost function may comprise terms for target feature side wall angle, side wall angle linearity, side wall angle symmetry, pattern placement error, and/or other terms.

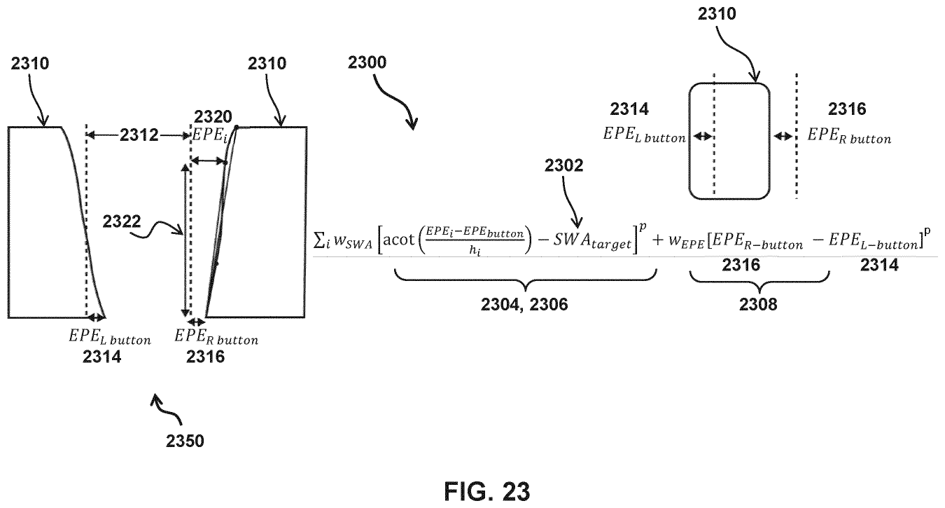

By way of a non-limiting example, FIG. 23 illustrates an example custom cost function 2300. Custom cost function 2300 includes terms for target feature side wall angle 2302, side wall angle linearity 2304, side wall angle symmetry 2306, and pattern placement error 2308. These terms are weighted. In custom cost function 2300, w_{SWA} represents the weighting of the sidewall angle term in the custom cost function, and w_{EPE} represents the weighting of the EPEi angle term in the custom cost function. FIG. 23 illustrates how the terms in custom cost function 2300 relate to a pattern target feature 2310 that has sidewalls. FIG. 23 illustrates a target critical dimension (CD) 2312, and the physical representations of various custom cost function 2300 “buttons” (e.g., variables that affect the overall cost). For example, FIG. 23 illustrates left and right edge placement error (EPE) buttons 2314, 2316 (in both a cross sectional view 2350 and an overhead view 2360). FIG. 23 also illustrates EPEᵢ 2320—edge placement error, the error between the printed resist profile to the target edge evaluation at evaluation points, and hᵢ 2322 (e.g., a height associated with a sidewall). As these individual buttons change, the overall cost generated by cost function 2300 changes.

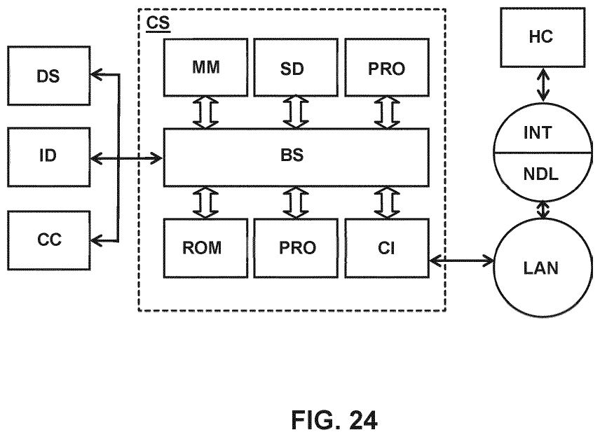

FIG. 24 is a block diagram of an example computer system CS, according to an embodiment. Computer system CS may assist in implementing the methods, flows, or the apparatus disclosed herein. Computer system CS includes a bus BS or other communication mechanism for communicating information, and a processor PRO (or multiple processors) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions to be executed by processor PRO, for example. Computer system CS includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

In some embodiments, portions of one or more methods described herein may be performed by computer system CS in response to processor PRO executing one or more sequences of one or more instructions contained in main memory MM. Such instructions may be read into main memory MM from another computer-readable medium, such as storage device SD. Execution of the sequences of instructions contained in main memory MM causes processor PRO to perform the process steps described herein. One or more processors in a multi-processing arrangement may also be employed to execute the sequences of instructions contained in main memory MM. In some embodiments, hard-wired circuitry may be used in place of or in combination with software instructions. Thus, the description herein is not limited to any specific combination of hardware circuitry and software.

The term “computer-readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the features described herein. Transitory computer-readable media can include a carrier wave or other propagating electromagnetic signal.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) both use electrical, electromagnetic or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

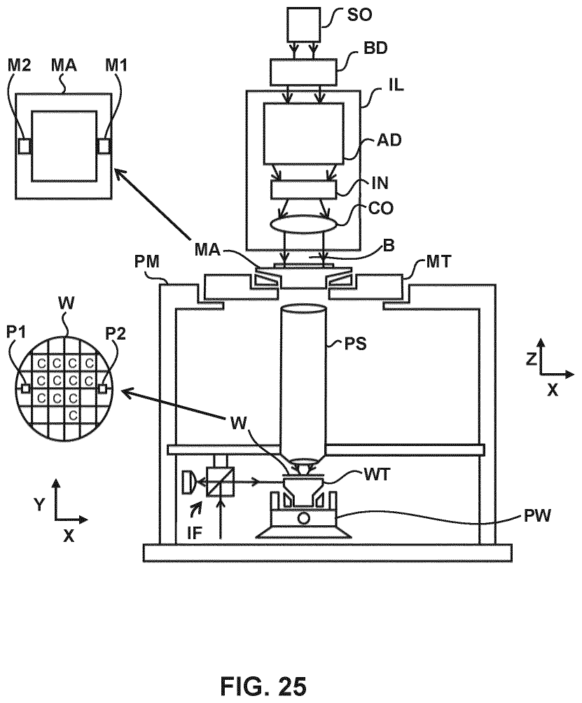

FIG. 25 is a schematic diagram of a lithographic projection apparatus, according to one or more embodiments. The lithographic projection apparatus can include an illumination system IL, a first object table MT, a second object table WT, and a projection system PS.

Illumination system IL can condition a beam B of radiation. In this particular case, the illumination system also comprises a radiation source SO.

First object table (e.g., patterning device table) MT can be provided with a patterning device holder to hold a patterning device MA (e.g., a reticle), and connected to a first positioner PM to accurately position the patterning device with respect to item PS.

Second object table (substrate table) WT can be provided with a substrate holder to hold a substrate W (e.g., a resist-coated silicon wafer), and connected to a second positioner PW to accurately position the substrate with respect to item PS.

Projection system (“lens”) PS (e.g., a refractive, catoptric or catadioptric optical system) can image an irradiated portion of the patterning device MA onto a target portion C (e.g., comprising one or more dies) of the substrate W.

As depicted, the apparatus can be of a transmissive type (i.e., has a transmissive patterning device). However, in general, it may also be of a reflective type, for example (with a reflective patterning device). The apparatus may employ a different kind of patterning device to classic mask; examples include a programmable mirror array or LCD matrix.

The source SO (e.g., a mercury lamp or excimer laser, LPP (laser produced plasma) EUV source) produces a beam of radiation. This beam is fed into illumination system (illuminator) IL, either directly or after having traversed conditioning apparatuses, such as a beam expander, for example. The illuminator IL may comprise adjusting device AD for setting the outer and/or inner radial extent (commonly referred to as σ-outer and σ-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

In some embodiments, source SO may be within the housing of the lithographic projection apparatus (as is often the case when source SO is a mercury lamp, for example), but that it may also be remote from the lithographic projection apparatus, the radiation beam that it produces being led into the apparatus (e.g., with the aid of suitable directing mirrors); this latter scenario can be the case when source SO is an excimer laser (e.g., based on KrF, ArF or F2 lasing).

The beam B can subsequently intercept patterning device MA, which is held on a patterning device table MT. Having traversed patterning device MA, the beam B can pass through the lens, which focuses beam B onto target portion C of substrate W. With the aid of the second positioning apparatus (and interferometric measuring apparatus IF), the substrate table WT can be moved accurately, e.g. so as to position different target portions C in the path of beam B. Similarly, the first positioning apparatus can be used to accurately position patterning device MA with respect to the path of beam B, e.g., after mechanical retrieval of the patterning device MA from a patterning device library, or during a scan. In general, movement of the object tables MT, WT can be realized with the aid of a long-stroke module (coarse positioning) and a short-stroke module (fine positioning). However, in the case of a stepper (as opposed to a step-and-scan tool) patterning device table MT may just be connected to a short stroke actuator, or may be fixed.

The depicted tool can be used in two different modes, step mode and scan mode. In step mode, patterning device table MT is kept essentially stationary, and an entire patterning device image is projected in one go (i.e., a single “flash”) onto a target portion C. Substrate table WT can be shifted in the x and/or y directions so that a different target portion C can be irradiated by beam B.

In scan mode, essentially the same scenario applies, except that a given target portion C is not exposed in a single “flash.” Instead, patterning device table MT is movable in a given direction (the so-called “scan direction”, e.g., the y direction) with a speed v, so that projection beam B is caused to scan over a patterning device image; concurrently, substrate table WT is simultaneously moved in the same or opposite direction at a speed V=Mv, in which M is the magnification of the lens (typically, M=¼ or ⅕). In this manner, a relatively large target portion C can be exposed, without having to compromise on resolution.

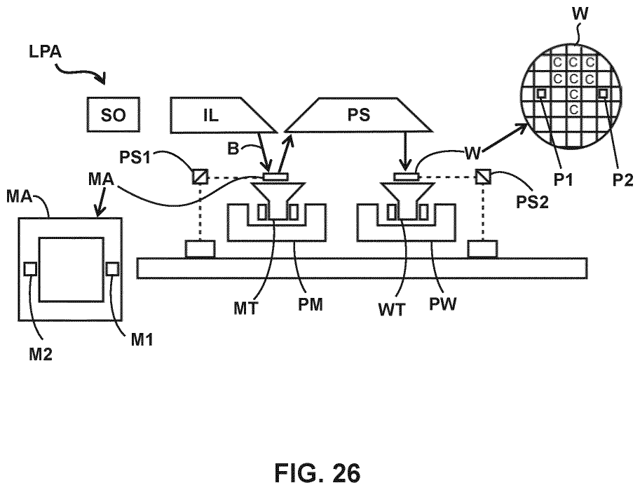

FIG. 26 is a schematic diagram of another lithographic projection apparatus (LPA), according to one or more embodiments. LPA can include source collector module SO, illumination system (illuminator) IL configured to condition a radiation beam B (e.g. EUV radiation), support structure MT, substrate table WT, and projection system PS.

Support structure (e.g. a patterning device table) MT can be constructed to support a patterning device (e.g. a mask or a reticle) MA and connected to a first positioner PM configured to accurately position the patterning device.

Substrate table (e.g. a wafer table) WT can be constructed to hold a substrate (e.g. a resist coated wafer) W and connected to a second positioner PW configured to accurately position the substrate.

Projection system (e.g. a reflective projection system) PS can be configured to project a pattern imparted to the radiation beam B by patterning device MA onto a target portion C (e.g. comprising one or more dies) of the substrate W.

As here depicted, LPA can be of a reflective type (e.g. employing a reflective patterning device). It is to be noted that because most materials are absorptive within the EUV wavelength range, the patterning device may have multilayer reflectors comprising, for example, a multi-stack of molybdenum and silicon. In one example, the multi-stack reflector has 40 layer pairs of molybdenum and silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Illuminator IL can receive an extreme ultra violet radiation beam from source collector module SO. Methods to produce EUV radiation include, but are not necessarily limited to, converting a material into a plasma state that has at least one element, e.g., xenon, lithium or tin, with one or more emission lines in the EUV range. In one such method, often termed laser produced plasma (“LPP”) the plasma can be produced by irradiating a fuel, such as a droplet, stream or cluster of material having the line-emitting element, with a laser beam. Source collector module SO may be part of an EUV radiation system including a laser for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation.

In such cases, the laser may not be considered to form part of the lithographic apparatus and the radiation beam can be passed from the laser to the source collector module with the aid of a beam delivery system comprising, for example, suitable directing mirrors and/or a beam expander. In other cases, the source may be an integral part of the source collector module, for example when the source is a discharge produced plasma EUV generator, often termed as a DPP source.

Illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B can be incident on the patterning device (e.g., mask) MA, which is held on the support structure (e.g., patterning device table) MT, and is patterned by the patterning device. After being reflected from the patterning device (e.g. mask) MA, the radiation beam B passes through the projection system PS, which focuses the beam onto a target portion C of the substrate W. With the aid of the second positioner PW and position sensor PS2 (e.g. an interferometric device, linear encoder or capacitive sensor), the substrate table WT can be moved accurately, e.g. so as to position different target portions C in the path of radiation beam B Similarly, the first positioner PM and another position sensor PS1 can be used to accurately position the patterning device (e.g. mask) MA with respect to the path of the radiation beam B. Patterning device (e.g. mask) MA and substrate W may be aligned using patterning device alignment marks M1, M2 and substrate alignment marks P1, P2.

The depicted apparatus LPA could be used in at least one of the following modes, step mode, scan mode, and stationary mode.

In step mode, the support structure (e.g. patterning device table) MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed.

In scan mode, the support structure (e.g. patterning device table) MT and the substrate table WT are scanned synchronously while a pattern imparted to the radiation beam is projected onto target portion C (i.e. a single dynamic exposure). The velocity and direction of substrate table WT relative to the support structure (e.g. patterning device table) MT may be determined by the (de-) magnification and image reversal characteristics of the projection system PS.

In stationary mode, the support structure (e.g. patterning device table) MT is kept essentially stationary holding a programmable patterning device, and substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array.

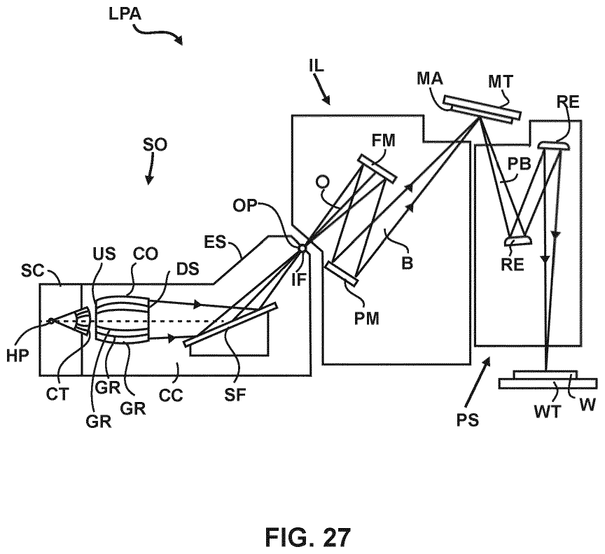

FIG. 27 is a detailed view of the lithographic projection apparatus LPA, according to one or more embodiments. As shown, LPA can include the source collector module SO, the illumination system IL, and the projection system PS. The source collector module SO is configured such that a vacuum environment can be maintained in an enclosing structure ES of the source collector module SO. An EUV radiation emitting hot plasma HP may be formed by a discharge produced plasma source. EUV radiation may be produced by a gas or vapor, for example Xe gas, Li vapor or Sn vapor in which the hot plasma HP is created to emit radiation in the EUV range of the electromagnetic spectrum. The hot plasma HP is created by, for example, an electrical discharge causing at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma HP is passed from a source chamber SC into a collector chamber CC via an optional gas barrier or contaminant trap CT (in some cases also referred to as contaminant barrier or foil trap) which is positioned in or behind an opening in source chamber SC. The contaminant trap CT may include a channel structure. Contamination trap CT may also include a gas barrier or a combination of a gas barrier and a channel structure. The contaminant trap or contaminant barrier CT further indicated herein at least includes a channel structure, as known in the art.

The collector chamber CC may include a radiation collector CO which may be a so-called grazing incidence collector. Radiation collector CO has an upstream radiation collector side US and a downstream radiation collector side DS. Radiation that traverses radiation collector CO can be reflected off a grating spectral filter SF to be focused in a virtual source point IF along the optical axis indicated by the dot-dashed line ‘O’. The virtual source point IF can be referred to as the intermediate focus, and the source collector module can be arranged such that the intermediate focus IF is located at or near an opening OP in the enclosing structure ES. The virtual source point IF is an image of the radiation emitting plasma HP.

Subsequently the radiation traverses the illumination system IL, which may include a facetted field mirror device FM and a facetted pupil mirror device PM arranged to provide a desired angular distribution of the radiation beam B, at the patterning device MA, as well as a desired uniformity of radiation amplitude at the patterning device MA. Upon reflection of the beam of radiation B at the patterning device MA, held by the support structure MT, a patterned beam PB is formed and the patterned beam PB is imaged by the projection system PS via reflective elements RE onto a substrate W held by the substrate table WT.

More elements than shown may generally be present in illumination optics unit IL and projection system PS. The grating spectral filter SF may optionally be present, depending upon the type of lithographic apparatus. Further, there may be more mirrors present than those shown in the figures, for example there may be 1-6 additional reflective elements present in the projection system PS.

Collector optic CO can be a nested collector with grazing incidence reflectors GR, just as an example of a collector (or collector mirror). The grazing incidence reflectors GR are disposed axially symmetric around the optical axis O and a collector optic CO of this type may be used in combination with a discharge produced plasma source, often called a DPP source.

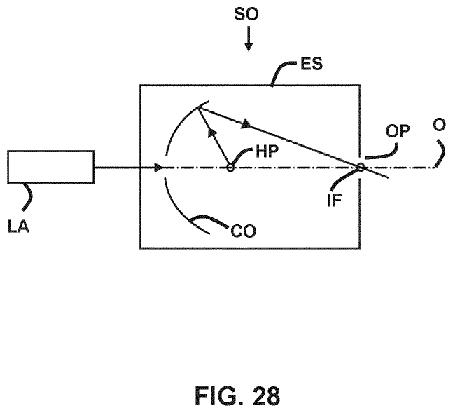

FIG. 28 is a detailed view of source collector module SO of lithographic projection apparatus LPA, according to one or more embodiments. Source collector module SO may be part of an LPA radiation system. A laser LA can be arranged to deposit laser energy into a fuel, such as xenon (Xe), tin (Sn) or lithium (Li), creating the highly ionized plasma HP with electron temperatures of several 10's of eV. The energetic radiation generated during de-excitation and recombination of these ions is emitted from the plasma, collected by a near normal incidence collector optic CO and focused onto the opening OP in the enclosing structure ES.

The embodiments may further be described using the following clauses:

1. A non-transitory computer readable medium having instructions thereon, the instructions when executed by a computer causing the computer to:

place one or more assist features in a design layout in one or more locations adjacent to one or more target features in the design layout, the design layout configured to be used to pattern a substrate, the one or more assist features placed based on two or more different focus positions on the substrate; and

shift the design layout based on the two or more different focus positions and the one or more placed assist features, the shifting configured to enhance the one or more target features when the one or more target features are patterned on the substrate.

2. The medium of clause 1, wherein shifting the design layout comprises repositioning a patterning device pattern, determined based on the design layout, relative to the substrate.
3. The medium of any of clauses 1-2, wherein the enhancing is achieved by reducing a shift that would otherwise be caused by across slit asymmetry for a slit through which imaging radiation passes during imaging of the substrate.
4. The medium of clause 3, wherein the across slit asymmetry is associated with a Z2 Zernike polynomial or with collateral Zernike polynomial.
5. The medium of any of clauses 1-4, wherein placing the one or more assist features and shifting the design layout comprises simulating adjustment of a numerical aperture (NA), a sigma, a best focus, and/or a wavelength peak separation associated with imaging radiation to optimize the one or more assist features.
6. The medium of clause 5, wherein the optimization comprises through slit optimization.
7. The medium of any of clauses 1-6, wherein placing the one or more assist features and shifting the design layout comprises electromagnetic or scalar modeling of the one or more assist features and the shifting of the design layout with an electronic model.
8. The medium of any of clauses 1-7, wherein the instructions are further configured to cause the computer to determine through slit assist feature rules and place the one or more assist features based on the optimized assist features, and apply a full field optical proximity correction for the design layout, the full field optical proximity correction being model based or rules based, applying the full field optical proximity correction comprising:

applying, based on the shifted design layout, a through slit repositioning shift to the one or more target features of the design layout;

applying the optimized through slit assist features; and

applying a main feature bias.

9. The medium of clause 8, wherein the through slit assist feature rules are determined based on a custom cost function, the custom cost function comprising terms for target feature side wall angle, side wall angle linearity, side wall angle symmetry, and pattern placement error.
10. The medium of any of clauses 1-9, wherein the one or more target features have sidewalls, and wherein placing the one or more assist features and shifting the design layout are performed to achieve a required sidewall angle, side wall angle linearity, and/or side wall angle symmetry.
11. The medium of any of clauses 1-10, wherein optimized imaging radiation having two or more different wavelengths controls the two or more different focus positions on the substrate for a single exposure of the substrate to the imaging radiation.
12. The medium of any of clauses 1-11, wherein the one or more assist features and the shifted design layout are configured to enhance the one or more target features in the substrate by improving one or both of a symmetry of the one or more target features, or placement of the one or more target features, in the substrate.
13. The medium of any of clauses 1-12, wherein placing the one or more assist features comprises determining a quantity, a shape, a size, a position, and/or an orientation of the one or more assist features relative to the one or more target features based on two or more different wavelengths of imaging radiation associated with the different focus positions.
14. The medium of clause 13, wherein the shape, size, position, and/or orientation of the one or more assist features are configured such that the one or more assist features are not formed in the substrate.
15. The medium of any of clauses 1-14, wherein placing the one or more assist features and shifting the design layout are performed for a semiconductor manufacturing process.
16. A method for enhancing one or more target features when the one or more target features are patterned on a substrate, the method comprising:

placing one or more assist features in a design layout in one or more locations adjacent to one or more target features in the design layout, the design layout configured to be used to pattern the substrate, the one or more assist features placed based on two or more different focus positions on the substrate; and

shifting the design layout based on the two or more different focus positions and the one or more placed assist features, the shifting configured to enhance the one or more target features when the one or more target features are patterned on the substrate.

17. The method of clause 1, wherein shifting the design layout comprises repositioning a patterning device pattern, determined based on the design layout, relative to the substrate.
18. The method of any of clauses 16-17, wherein the enhancing is achieved by reducing a shift that would otherwise be caused by across slit asymmetry for a slit through which imaging radiation passes during imaging of the substrate.
19. The method of clause 18, wherein the across slit asymmetry is associated with a Z2 Zernike polynomial or with collateral Zernike polynomials.
20. The method of any of clauses 16-19, wherein placing the one or more assist features and shifting the design layout comprises simulating adjustment of a numerical aperture (NA), a sigma, a best focus, and/or a wavelength peak separation associated with imaging radiation to optimize the one or more placed assist features.
21. The method of clause 20, wherein the optimization comprises through slit optimization.
22. The method of any of clauses 16-21, wherein placing the one or more assist features and shifting the design layout comprises electromagnetic or scalar modeling of the one or more assist features and the shifting of the design layout with an electronic model.
23. The method of any of clauses 16-22, further comprising determining through slit assist feature rules and placing the one or more assist features based on the optimized assist features, and applying a full field optical proximity correction for the design layout, the full field optical proximity correction being model based or rules based, applying the full field optical proximity correction comprising:

applying, based on the shifted design layout, a through slit repositioning shift to the one or more target features of the design layout;

applying the optimized through slit assist features; and

applying a main feature bias.

24. The method of clause 23, wherein the through slit assist feature rules are determined based on a custom cost function, the custom cost function comprising terms for target feature side wall angle, side wall angle linearity, side wall angle symmetry, and pattern placement error.
25. The method of any of clauses 16-24, wherein the one or more target features have sidewalls, and wherein placing the one or more assist features and shifting the design layout are performed to achieve a required sidewall angle, side wall angle linearity, and/or side wall angle symmetry.
26. The method of any of clauses 16-25, wherein optimized imaging radiation having two or more different wavelengths controls the two or more different focus positions on the substrate for a single exposure of the substrate to the imaging radiation.
27. The method of any of clauses 16-26, wherein the one or more assist features and the shifted design layout are configured to enhance the one or more target features in the substrate by improving one or both of a symmetry of the one or more target features, or placement of the one or more target features, in the substrate.
28. The method of any of clauses 16-27, wherein placing the one or more assist features comprises determining a quantity, a shape, a size, a position, and/or an orientation of the one or more assist features relative to the one or more target features based on two or more different wavelengths of imaging radiation associated with the different focus positions.
29. The method of clause 28, wherein the shape, size, position, and/or orientation of the one or more assist features are configured such that the one or more assist features are not formed in the substrate.
30. The method of any of clauses 16-29, wherein placing the one or more assist features and shifting the design layout are performed for a semiconductor manufacturing process.
31. A method for enhancing target features of a pattern imaged onto a substrate, the method comprising:

determining two or more different focus positions on the substrate for imaging radiation; and

adding, based on the two or more different focus positions, one or more assist features to the pattern in one or more locations proximate to one or more of the target features of the pattern, the added one or more assist features configured to enhance the target features on the substrate.

32. The method of clause 31, wherein the two or more different focus positions on the substrate are for imaging radiation having two or more different wavelengths, and are determined for a single exposure of the substrate to the imaging radiation.
33. The method of clause 32, wherein the imaging radiation comprises two or more different colors that correspond to the two or more different wavelengths.
34. The method of any of clauses 32-33, where in the two or more different focus positions are determined based on the two or more different wavelengths of imaging radiation.
35. The method of any of clauses 31-34, wherein the one or more assist features comprise one or more sub-resolution assist features.
36. The method of any of clauses 31-35, wherein the added one or more assist features are configured to enhance the target features on the substrate by improving one or both of a symmetry of the target features of the pattern, or placement of the target features of the pattern, on the substrate.
37. The method of any of clauses 31-36, further comprising determining an image associated with the substrate by adding the one or more assist features to the pattern in the one or more locations proximate to one or more of the target features; and determining the image based on the one or more added assist features and the target features.
38. The method of clause 37, wherein the image is an aerial image.
39. The method of any of clauses 37-38, wherein determining the image based on the one or more added assist features and the one or more target features improves one or both of a symmetry of the target features of the pattern, or placement of the target features of the pattern, in the image.
40. The method of clause 39, wherein one or both of the symmetry of the target features of the pattern, or the placement of the target features of the pattern in the image are improved relative to a symmetry and/or placement of target features in a different image determined without considering the assist features.
41. The method of any of clauses 31-40, wherein adding the one or more assist features to the pattern in the one or more locations proximate to the one or more target features of the pattern comprises determining a shape, a size, a position, and/or an orientation of the one or more assist features relative to the one or more target features.
42. The method of any of clauses 31-41, wherein adding the one or more assist features to the pattern enhances the target features by reducing a shift caused by across slit asymmetry for a slit of a multifocal lithographic imaging apparatus.
43. The method of clause 42, wherein the across slit asymmetry is associated with a Z2 Zernike polynomial.
44. The method of clause 42, wherein the across slit asymmetry is associated with collateral Zernike polynomials.
45. The method of any of clauses 42-44, wherein different ones of the one or more assist features correspond to one or more different slit positions in the slit.
46. The method of any of clauses 31-45, wherein a shape, size, position, and/or orientation of the one or more assist features are configured such that the one or more assist features are not formed on the substrate.
47. The method of any of clauses 31-46, wherein adding one or more assist features to the pattern in the one or more locations proximate to the one or more target features of the pattern comprises electronically modeling the one or more assist features in the pattern.
48. The method of any of clauses 31-47, wherein the pattern comprises a mask pattern.
49. The method of any of clauses 31-48, wherein determining the two or more different focus positions on the substrate for the imaging radiation; and adding the one or more assist features to the pattern in the one or more locations proximate to the one or more target features of the pattern are performed for a semiconductor manufacturing process.
50. The method of any of clauses 31-49, wherein adding one or more assist features to the pattern in one or more locations proximate to one or more target features of the pattern comprises adding one assist feature on one side of a given target feature.
51. The method of any of clauses 31-50, wherein adding one or more assist features to the pattern in one or more locations proximate to one or more target features of the pattern comprises adding two or more assist features on one side of a given target feature.
52. The method of any of clauses 31-51, wherein adding one or more assist features to the pattern in one or more locations proximate to one or more target features of the pattern comprises adding at least one assist feature on each of two different sides of a given target feature.
53. A non-transitory computer readable medium having instructions thereon, the instructions when executed by a computer implementing the method of any of clauses 31-52.
54. A non-transitory computer readable medium having instructions thereon, the instructions when executed by a computer causing the computer to:

determine two or more different focus positions on a substrate for imaging radiation; and

add, based on the two or more different focus positions, one or more assist features to a pattern in one or more locations proximate to one or more target features of the pattern, the added one or more assist features configured to enhance the target features on the substrate.

55. The medium of clause 54, wherein the two or more different focus positions on the substrate are for imaging radiation having two or more different wavelengths, and are determined for a single exposure of the substrate to the imaging radiation.
56. The medium of any of clauses 54-55, wherein the one or more assist features comprise one or more sub-resolution assist features.
57. The medium of any of clauses 54-56, wherein the added one or more assist features are configured to enhance the target features on the substrate by improving one or both of a symmetry of the target features of the pattern, or placement of the target features of the pattern, on the substrate.
58. The medium of any of clauses 54-57, wherein the instructions are further configured to cause the computer to determine an aerial image associated with the substrate by adding the one or more assist features to the pattern in the one or more locations proximate to one or more of the target features; and determine the aerial image based on the one or more added assist features and the target features.
59. The medium of clause 58, wherein one or both of the symmetry of the target features of the pattern, or the placement of the target features of the pattern in the aerial image are improved relative to a symmetry and/or placement of target features in a different image determined without considering the assist features.
60. The medium of any of clauses 54-59, wherein adding the one or more assist features to the pattern in the one or more locations proximate to the one or more target features of the pattern comprises determining a shape, a size, a position, and/or an orientation of the one or more assist features relative to the one or more target features.
61. The medium of any of clauses 54-60, wherein adding the one or more assist features to the pattern enhances the target features by reducing a shift caused by across slit asymmetry for a slit of a multifocal lithographic imaging apparatus.
62. The medium of clause 61, wherein different ones of the one or more assist features correspond to one or more different slit positions in the slit.
63. The medium of any of clauses 54-62, wherein a shape, size, position, and/or orientation of the one or more assist features are configured such that the one or more assist features are not formed on the substrate.
64. The medium of any of clauses 54-63, wherein adding one or more assist features to the pattern in the one or more locations proximate to the one or more target features of the pattern comprises electronically modeling the one or more assist features in the pattern.
65. A lithography apparatus, the apparatus comprising:

an illumination source and projection optics configured to image a pattern onto a substrate; and

one or more processors configured by machine readable instructions to:

determine two or more different focus positions on the substrate for imaging radiation; and add, based on the two or more different focus positions, one or more assist features to the pattern in one or more locations proximate to one or more of the target features of the pattern, the added one or more assist features configured to enhance the target features on the substrate.
66. The apparatus of clause 65, wherein the two or more different focus positions on the substrate are for imaging radiation having two or more different wavelengths, and are determined for a single exposure of the substrate to the imaging radiation.
67. The apparatus of any of clauses 65-66, wherein the one or more assist features comprise one or more sub-resolution assist features.
68. The apparatus of any of clauses 65-67, wherein the added one or more assist features are configured to enhance the target features on the substrate by improving one or both of a symmetry of the target features of the pattern, or placement of the target features of the pattern, on the substrate.
69. The apparatus of any of clauses 65-68, wherein the one or more processors are further configured to determine an image associated with the substrate by adding the one or more assist features to the pattern in the one or more locations proximate to one or more of the target features; and determine the image based on the one or more added assist features and the target features.
70. The apparatus of clause 69, wherein the image is an aerial image.
71. The apparatus of any of clauses 65-70, wherein the one or more processors are configured such that adding the one or more assist features to the pattern in the one or more locations proximate to the one or more target features of the pattern comprises determining a shape, a size, a position, and/or an orientation of the one or more assist features relative to the one or more target features.
72. The apparatus of any of clauses 65-71, wherein the one or more processors are configured such that adding the one or more assist features to the pattern enhances the target features by reducing a shift caused by across slit asymmetry for a slit of a multifocal lithographic imaging apparatus.
73. The apparatus of clause 72, wherein different ones of the one or more assist features correspond to one or more different slit positions in the slit.
74. The apparatus of any of clauses 65-73, wherein the one or more processors are configured such that adding one or more assist features to the pattern in one or more locations proximate to one or more target features of the pattern comprises adding one assist feature on one side of a given target feature.
75. The apparatus of any of clauses 65-74, wherein the one or more processors are configured such that adding one or more assist features to the pattern in one or more locations proximate to one or more target features of the pattern comprises adding two or more assist features on one side of a given target feature.
76. A method for enhancing target features of a pattern imaged onto a substrate, the method comprising:

using imaging radiation to create two or more different focus positions on the substrate;

adding, based on the two or more different focus positions, one or more assist features to the pattern in one or more locations proximate to one or more of the target features of the pattern, the added one or more assist features configured to enhance the target features on the substrate; and

causing the target features of the pattern to be imaged onto the substrate based on the one or more added assist features and the target features.

77. A computer implemented method to enhance a process of imaging a portion of a design layout onto substrate, the method comprising:

determining two or more different focus positions on the substrate for imaging radiation; and

placing, based on the two or more different focus positions, one or more assist features asymmetrically into the design layout for imaging in one or more locations proximate to a target feature in the design layout for imaging.

The concepts disclosed herein may simulate or mathematically model any generic imaging system for imaging sub wavelength features, and may be especially useful with emerging imaging technologies capable of producing increasingly shorter wavelengths. Emerging technologies already in use include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-50 nm by using a synchrotron or by hitting a material (either solid or a plasma) with high energy electrons in order to produce photons within this range.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

In addition, the combination and sub-combinations of disclosed elements may comprise separate embodiments. For example, adding single or multiple assist features and/or the shifting as described herein may comprise their own separate embodiments, or they may be included with one or more other embodiments described herein.

The descriptions above are intended to be illustrative, not limiting. Thus, it will be apparent to one skilled in the art that modifications may be made as described without departing from the scope of the claims set out below.

1. A non-transitory computer readable medium having instructions therein, the instructions, when executed by a computer system, configured to cause the computer system to at least:
determine two or more different focus positions on a substrate for imaging radiation; and
add, based on the two or more different focus positions, one or more assist features to a pattern in one or more locations proximate to one or more target features of the pattern, the added one or more assist features configured to enhance the one or more target features on the substrate.

2. The medium of claim 1, wherein the two or more different focus positions on the substrate are for imaging radiation having two or more different wavelengths, and are determined for a single exposure of the substrate to the imaging radiation.

3. The medium of claim 1, wherein the one or more assist features comprise one or more sub-resolution assist features.

4. The medium of claim 1, wherein the added one or more assist features are configured to enhance the one or more target features on the substrate by improving a symmetry of target features of the pattern, and/or placement of target features of the pattern, on the substrate.

5. The medium of claim 1, wherein the instructions are further configured to cause the computer system to:
place the one or more assist features into the pattern in the one or more locations proximate to the one or more target features; and
determine the aerial image based on the one or more placed assist features and the one or more target features.

6. The medium of claim 5, wherein symmetry of target features of the pattern, and/or placement of target features of the pattern, in the aerial image is improved relative to a symmetry and/or placement of target features in a different image determined without considering the assist features.

7. The medium of claim 1, wherein the instructions configured to cause the computer system to add the one or more assist features to the pattern in the one or more locations proximate to the one or more target features of the pattern are further configured to cause the computer system to determine a shape, a size, a position, and/or an orientation of the one or more assist features relative to the one or more target features.

8. The medium of claim 1, wherein the addition of the one or more assist features to the pattern enhances the one or more target features by reducing a shift caused by across slit asymmetry for a slit of a multifocal lithographic imaging apparatus.

9. The method of claim 8, wherein the across slit asymmetry is associated with a Z2 Zernike polynomial.

10. The method of claim 8, wherein the across slit asymmetry is associated with collateral Zernike polynomials.

11. The medium of claim 8, wherein different ones of the one or more assist features correspond to one or more different slit positions in the slit.

12. The medium of claim 1, wherein a shape, size, position, and/or orientation of the one or more assist features are configured such that the one or more assist features are not formed on the substrate.

13. The medium of claim 1, wherein the instructions configured to cause the computer system to add the one or more assist features to the pattern in the one or more locations proximate to the one or more target features of the pattern are further configured to cause the computer system to electronically model the one or more assist features in the pattern.

14. A method to enhance a process of imaging a portion of a design layout onto a substrate, the method comprising:
determining two or more different focus positions on the substrate for imaging radiation; and
placing, by a hardware computer system based on the two or more different focus positions, one or more assist features asymmetrically into the design layout for imaging in one or more locations proximate to a target feature in the design layout for imaging.

15. The method of claim 14, further comprising causing the one or more target features of the design layout to be imaged onto the substrate based on the one or more placed assist features and the one or more target features.

16. The method of claim 14, wherein the two or more different focus positions on the substrate are for imaging radiation having two or more different wavelengths, and are determined for a single exposure of the substrate to the imaging radiation.

17. The method of claim 14, wherein the placed one or more assist features are configured to enhance the one or more target features on the substrate by improving a symmetry of target features of the design layout, and/or placement of target features of the design layout, on the substrate.

18. The method of claim 14, further comprising determining an aerial image associated with the substrate using the placed one or more assist features and the one or more target features.

19. The method of claim 14, wherein the placing of the one or more assist features enhances the one or more target features by reducing a shift caused by across slit asymmetry for a slit of a multifocal lithographic imaging apparatus.

20. The method of claim 19, wherein the across slit asymmetry is associated with a Z2 Zernike polynomial or associated with collateral Zernike polynomials.
